(19) United States
(12) Patent Application Publication
(10) Pub. No.: US 2021/0296605 A1
(43) Pub. Date: Sep. 23, 2021

(54) LIGHT-EMITTING DEVICE AND APPARATUS INCLUDING THE SAME

(71) Applicant: Samsung Display Co., Ltd., Yongin-si (KR)

(72) Inventors: Junwoo PARK, Yongin-si (KR); Myoungjin PARK, Yongin-si (KR); Sooho LEE, Yongin-si (KR); Yunhyuk KO, Yongin-si (KR); Sungwoon KIM, Yongin-si (KR); Minki NAM, Yongin-si (KR); Jaekook HA, Yongin-si (KR)

(21) Appl. No.: 17/107,411

(22) Filed: Nov. 30, 2020

(30) Foreign Application Priority Data
Mar. 19, 2020 (KR) 10-2020-0034053

(51) Int. Cl. H01L 51/50

(52) U.S. Cl. CPC H01L 51/502; H01L 51/5056; H01L 2251/308; H01L 51/5092; H01L 2251/306; H01L 51/5072

(57) ABSTRACT

A light-emitting device includes: a first electrode; a second electrode facing the first electrode; an emission layer between the first electrode and the second electrode and including quantum dots; a hole transport region between the first electrode and the emission layer; and an electron sink layer between the emission layer and the hole transport region and including an electron transport material, wherein the electron transport material includes a metal, a metal oxide, a metal-containing material, or any combination thereof.

### CROSS-REFERENCE TO RELATED APPLICATION

This application claims priority to and the benefit of Korean Patent Application No. 10-2020-0034053, filed on Mar. 19, 2020, in the Korean Intellectual Property Office, the disclosure of which is incorporated herein in its entirety by reference.

### BACKGROUND

### 1. Field

One or more embodiments relate to a light-emitting device and an apparatus including the same.

### 2. Description of Related Art

Light-emitting devices are devices in which electrical energy is converted into light energy. From among light-emitting devices, quantum dot light-emitting devices have high color purity and high luminescence efficiency, and may produce full-color images.

In a light-emitting device, a first electrode is disposed on a substrate, and a hole transport region, an emission layer, an electron transport region, and a second electrode are sequentially formed on the first electrode. Holes provided from the first electrode may move toward the emission layer through the hole transport region, and electrons provided from the second electrode may move toward the emission layer through the electron transport region. Carriers, such as holes and electrons, recombine in the emission layer to produce excitons. These excitons transit from an excited state to a ground state, thereby generating light.

An emission layer in a quantum dot light-emitting device is formed by stacking quantum dots in several layers for efficient charge injection, but in this case, pinholes or cracks may occur in the emission layer, thereby acting as a current leakage path and adversely affecting the lifespan of the device.

Therefore, there is still a need for the development of a high-quality light-emitting device with no defects in an emission layer, as well as improved efficiency and improved lifespan.

### SUMMARY

An aspect according to one or more embodiments is directed toward a quantum dot light-emitting device for minimizing or reducing leakage of electrons at an interface between a quantum dot emission layer and a hole transport layer.

Additional aspects will be set forth in part in the description which follows and, in part, will be apparent from the description, or may be learned by practice of the presented embodiments of the disclosure.

According to an embodiment, a light-emitting device includes

a first electrode,

a second electrode facing the first electrode,

an emission layer between the first electrode and the second electrode and including quantum dots,

a hole transport region between the first electrode and the emission layer, and

an electron sink layer between the emission layer and the hole transport region and including an electron transport material,

wherein the electron transport material includes a metal, a metal oxide, a metal-containing material, or any combination thereof.

In one embodiment, the electron transport material may include an alkali metal, an alkaline earth metal, a rare earth metal, a transition metal, the one or more metal oxides thereof, an alkaline metal complex, an alkaline earth metal complex, or any combination thereof.

In one embodiment, the electron transport material may include Yb, Ag, ZnO, TiO₂, WO₃, SnO₂, ITO, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Liq, or any combination thereof.

In one embodiment, the electron transport material may include Yb, Ag, ITO, ZnO, ZnMgO, Liq, or any combination thereof.

In one embodiment, the electron sink layer may consist of the electron transport material.

In one embodiment, the hole transport region may include a hole transport material, and the hole transport material and the electron transport material may be different from each other.

In one embodiment, the electron sink layer may be at an interface between the hole transport region and the emission layer.

In one embodiment, the hole transport region may include a hole injection layer, a hole transport layer, a buffer layer, or any combination thereof, and the electron sink layer may be at an interface between the emission layer and a layer adjacent to the second electrode from among layers included in the hole transport region.

In one embodiment, the hole transport region may include a hole transport layer, and the electron sink layer may be at an interface between the hole transport layer and the emission layer.

In one embodiment, a thickness of the electron sink layer may be from about 0.01 nm to about 20 nm. In one embodiment, the thickness of the electron sink layer may be from about 0.05 nm to about 15 nm. In one embodiment, the thickness of the electron sink layer may be from about 0.1 nm to about 10 nm.

In one embodiment, the quantum dots in the emission layer may include: a Group II-VI semiconductor compound; a Group III-VI semiconductor compound; a Group III-V semiconductor compound; a Group IV-VI semiconductor compound; a Group IV element or compound; a Group semiconductor compound; or any combination thereof.

In one embodiment, the quantum dots in the emission layer may include a Group III-V semiconductor compound.

In one embodiment, the quantum dots in the emission layer may include InN, InP, InAs, InSb, InAsP, InGaAs, InGaP, GaP, GaN, GaSb, GaAs, ZnS, ZnSe, ZnTe, ZnO, HgS, HgSe, HgTe, ZnSeS, ZnSeTe, ZnSTe, CdS, CdSe, CdTe, CdSeS, CdSeTe, CdSTe, HgSeS, HgSeTe, HgSTe, CdZnS, CdZnSe, CdZnTe, CdHgS, CdHgSe, CdHgTe, HgZnS, HgZnSe, HgZnTe, ZnCdSe, AgInS, AgInS₂, CuInS, CuInS₂, CuGaO₂, AgGaO₂, AgAlO₂, CulnZnS, In₂S₃, Ga₂S₃, InGaS₃, InGaSe₃, or any combination thereof.

In one embodiment, the quantum dots in the emission layer may include InP and may not include cadmium (Cd).

In one embodiment, the quantum dots in the emission layer may each have a core-shell structure including a core including a first semiconductor crystal and a shell including a second semiconductor crystal.

In one embodiment, the first semiconductor crystal may include InN, InP, InAs, InSb, InAsP, InGaAs, InGaP, GaP, GaN, GaSb, GaAs, ZnS, ZnSe, ZnTe, HgS, HgSe, HgTe, ZnSeS, ZnSeTe, CdS, CdSe, CdTe, CdSeTe, CdZnSe, ZnCdSe, AgInS₂, CuInS, CulnZnS, or any combination thereof, and the second semiconductor crystal may include ZnS, ZnSe, ZnTe, ZnSeS, ZnSeTe, In₂S₃, Ga₂S₃, or any combination thereof.

In one embodiment, the first electrode may be an anode, the second electrode may be a cathode, and an electron transport region may be further between the emission layer and the second electrode.

In one embodiment, the electron transport region may include ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC60BM, PC70BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof.

In one embodiment, the electron transport region may include an electron transport layer, and the electron transport layer may include ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC₆₀BM, PC₇₀BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof.

In one embodiment, the electron transport region may include an electron transport layer, and the electron transport layer may have a thickness of about 20 nm to about 150 nm.

According to another embodiment, an apparatus includes a thin-film transistor including a source electrode, a drain electrode, and an activation layer; and the light-emitting device, wherein the first electrode of the light-emitting device may be electrically connected with the source electrode or the drain electrode of the thin-film transistor.

### BRIEF DESCRIPTION OF THE DRAWINGS

The above and other aspects, features, and enhancements of certain embodiments of the disclosure will be more apparent from the following description taken in conjunction with the accompanying drawings, in which:

FIG. 1 is a schematic view of a structure of a light-emitting device according to an embodiment of the present disclosure; and

FIG. 2 is an efficiency-luminance graph of light-emitting devices manufactured according to Example 1 and Comparative Example 1.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present disclosure can apply various suitable transformations and can have various suitable examples, specific examples will be illustrated in the drawings and described in more detail in the detailed description. Effects and features of the present disclosure, and methods of achieving the same will be clarified by referring to Examples described in more detail later with reference to the drawings. However, the present disclosure is not limited to the examples disclosed below and may be implemented in various suitable forms.

Hereinafter, embodiments of the present disclosure will be described in more detail with reference to the accompanying drawings. The same or corresponding components will be denoted by the same reference numerals, and thus redundant description thereof will be omitted (e.g., will not be repeated).

It will be understood that although the terms “first,” “second,” etc., may be used herein to describe various components, these components should not be limited by these terms. These components are only used to distinguish one component from another.

As used herein, the singular forms “a,” “an” and “the” are each intended to include the plural forms as well, unless the context clearly indicates otherwise.

It will be further understood that the terms “comprises” and/or “comprising” as used herein specify the presence of stated features or components, but do not preclude the presence or addition of one or more other features or components.

In the following embodiments, when various components such as layers, films, regions, plates, etc., are said to be “on” another component, it can be directly on the other component or intervening components may be present. Sizes of elements in the drawings may be exaggerated for convenience of explanation. In other words, because sizes and thicknesses of components in the drawings are arbitrarily illustrated for convenience of explanation, the following embodiments of the present disclosure are not limited thereto.

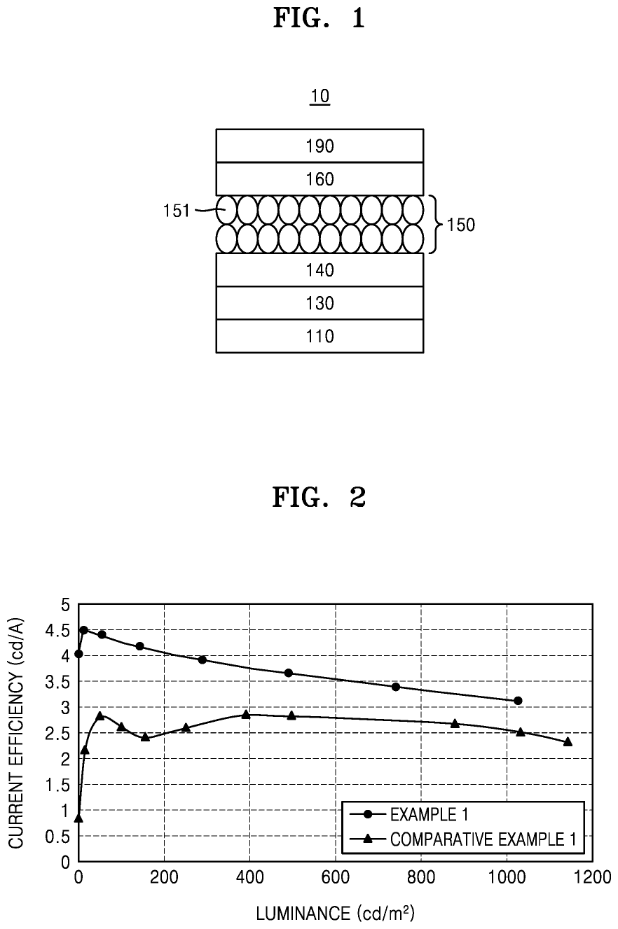

### [Description of FIG. 1]

FIG. 1 is a schematic cross-sectional view of a structure of a light-emitting device 10 according to an embodiment of the present disclosure.

Referring to FIG. 1, the light-emitting device 10 according to an embodiment includes: a first electrode 110; a second electrode 190 facing the first electrode 110; an emission layer 150 located between the first electrode 110 and the second electrode 190 and includes quantum dots; a hole transport region 130 between the first electrode 110 and the emission layer 150; and an electron sink layer 140 located between the emission layer 150 and the hole transport region 130 and includes an electron transport material.

In FIG. 1, the light-emitting device 10 further includes an electron transport region 160 between the emission layer 150 and the second electrode 190, but the electron transport region 160 may be omitted. In one embodiment, the light-emitting device 10 does not include the electron transport region.

In one embodiment, the first electrode 110 may be an anode, and the second electrode 190 may be a cathode.

The electron transport material may include a metal, a metal oxide, a metal-containing material, or any combination thereof.

For example, the electron transport material may include an alkali metal, an alkaline earth metal, a rare earth metal, a transition metal, a metal oxide, a metal-containing material (e.g., an alkaline metal complex, and/or an alkaline earth metal complex), or any combination thereof.

For example, the alkali metal may include Li, Na, K, Rb, Cs, or any combination thereof.

For example, the alkaline earth metal may include Mg, Ca, Sr, Ba, or any combination thereof.

For example, the rare earth metal may include Sc, Y, Ce, Tb, Yb, Gd, or any combination thereof. For example, the rare earth metal may include Yb, but embodiments of the present disclosure are not limited thereto.

For example, the transition metal may include silver (Ag), but embodiments of the present disclosure are not limited thereto.

For example, the metal oxide may include an amorphous or crystalline inorganic material (such as ZnO, TiO₂, WO₃, and/or SnO₂), a conductive metal oxide (such as Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, and/or In-doped SnO₂), or any combination thereof, but embodiments of the present disclosure are not limited thereto.

For example, the metal-containing material may include an alkali metal complex, an alkaline earth metal complex, or any combination thereof. The alkaline metal complex may include a metal ion selected from Li ion, Na ion, K ion, Rb ion, and Cs ion, and a ligand coordinated with the metal ion. The alkaline earth metal complex may include a metal ion selected from Be ion, Mg ion, Ca ion, Sr ion, and Ba ion, and a ligand coordinated with the metal ion.

A ligand coordinated with the alkaline metal ion may be selected from hydroxyquinoline, hydroxyisoquinoline, hydroxybenzoquinoline, hydroxyacridine, hydroxyphenanthridine, hydroxyphenyloxazole, hydroxyphenylthiazole, hydroxydiphenyloxadiazole, hydroxydiphenylthiadiazole, hydroxyphenylpyridine, hydroxyphenylbenzimidazole, hydroxyphenylbenzothiazole, bipyridine, phenanthroline, and cyclopentadiene, but embodiments of the present disclosure are not limited thereto.

For example, the alkaline metal complex may include a Li complex. The Li complex may include lithium quinolate (Liq).

For example, the electron transport material may include Yb, Ag, ZnO, TiO₂, WO₃, SnO₂, ITO, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Liq, or any combination thereof, but embodiments of the present disclosure are not limited thereto.

In one embodiment, the electron transport material may include Yb, Ag, ITO, ZnO, ZnMgO, Liq, or any combination thereof, but embodiments of the present disclosure are not limited thereto.

In one embodiment, the electron sink layer 140 may consist of the electron transport material. The expression that the electron sink layer 140 “may consist of the electron transport material” denotes that the electron sink layer 140 does not substantially include other materials other than the electron transport material.

In one embodiment, the hole transport region 130 may include a hole transport material, and the hole transport material and the electron transport material may be different from each other. The hole transport material may be the same as described in connection with the compound that may be included in the hole transport region 130 described hereafter.

Because the electron sink layer 140 includes an electron transport material that is different from the hole transport material and has strong electron mobility characteristics, electrons may be substantially prevented from flowing from the emission layer 150 to the hole transport region 130, and thus stability and luminescence efficiency of the light-emitting device 10 may be improved.

In one embodiment, the electron sink layer 140 may be located at an interface between the hole transport region 130 and the emission layer 150.

The hole transport region 130 may include a hole injection layer, a hole transport layer, a buffer layer, or any combination thereof, and the electron sink layer 140 may be located at an interface between a layer adjacent to the second electrode 190 from among layers included in the hole transport region 130 and the emission layer 150. That is, the electron sink layer 140 may be located at an interface between the emission layer 150 and a layer that is the closest to the second electrode 190 from among layers included in the hole transport region 130.

The term “adjacent” denotes an arrangement relationship of layers that are closest to each other from among layers that are described to be adjacent.

For example, the hole transport region 130 may include a hole transport layer, and the electron sink layer 140 may be located at an interface between the hole transport layer and the emission layer 150.

In one or more embodiments, the hole transport region 130 may include a hole injection layer and a hole transport layer that are sequentially located from the first electrode 110, and the electron sink layer 140 may be located at an interface between the hole transport layer and the emission layer 150.

In one embodiment, a thickness of the electron sink layer 140 may be in a range from about 0.01 nm to about 20 nm, for example, from about 0.05 nm to about 15 nm, or, from about 0.1 nm to about 10 nm, but embodiments of the present disclosure are not limited thereto. When the thickness of the electron sink layer 140 is within these ranges, hole injection from the first electrode 110 to the emission layer 150 may be satisfactory.

When an emission layer includes quantum dots, because the emission layer is formed by stacking the quantum dots in one layer or several layers, unlike an organic film, a surface of the emission layer may not be uniform. Due to a structural defect at an interface of the emission layer, trapping of carriers such as electrons or holes is likely to occur at the interface. Carriers accumulated at the interface of the emission layer may cause degradation of material(s) of an adjacent organic layer or inorganic layer to thereby adversely affect lifespan (e.g., initial lifespan) and efficiency of a quantum dot light-emitting device. Because the light-emitting device according to an embodiment includes an electron sink layer between a hole transport region and an emission layer, the electron sink layer absorbs electrons moving from the quantum dot emission layer to the first electrode. Thus, the electrons may be prevented or substantially prevented from leaking to the hole transport region. Accordingly, the light-emitting device with improved efficiency and improved lifespan may be embodied.

In this case, when the electron sink layer is configured to be sufficiently thin, holes provided from the first electrode may be injected to the emission layer due to a tunneling effect.

In light-emitting devices, when holes are provided from the first electrode, electrons (which carry opposite charges provided from the second electrode) may move toward the first electrode. In this case, because electrons move in a direction opposite to movement of the holes at an interface between a hole transport region and an emission layer, electrons may be accumulated at the interface between the hole transport region and the emission layer or may move to the hole transport region to form a hole trap inside the hole transport region. Accordingly, holes are trapped in the hole transport region and are not efficiently injected to the emission layer, thereby lowering efficiency and lifespan of the light-emitting device.

The light-emitting device according to an embodiment includes an electron sink layer, and thus, when holes are injected to the emission layer, electrons may be prevented or substantially prevented from reversely moving to the hole transport region. Because the electron sink layer includes an electron transport material having strong electron transport characteristics, electrons flowing from the emission layer may be captured. Accordingly, hole trap formation in the hole transport region may be prevented or reduced, and hole injection to the emission layer may be smoothly performed. Accordingly, the light-emitting device may have high efficiency and long lifespan.

Furthermore, the electron sink layer may be formed at an interface between a hole transport region and an emission layer, thereby supplementing non-uniformity of surface morphology of an emission layer and preventing or substantially preventing carriers such as electrons and/or holes from trapping (e.g., from being trapped).

A method of forming the electron sink layer 140 is not particularly limited to methods generally utilized in the related art, but may be formed by, for example, a solution process.

When the electron sink layer 140 is formed by a solution process, a composition for forming the electron sink layer, wherein the composition includes the electron transport material dispersed in a solvent, is applied onto the hole transport region 130, and the solvent is volatilized (e.g., evaporated), to thereby form the electron sink layer 140. The solvent may include a generally available organic solvent.

The composition for forming an electron sink layer may be applied by utilizing one or more methods selected from spin coating, casting, micro-gravure coating, gravure coating, bar coating, roll coating, wire bar coating, dip coating, spray coating, screen printing, flexographic printing, offset printing, and ink-jet printing.

Quantum dots 151 may be quantum dots that can emit light through stimulation by light. For example, the quantum dots 151 may include: a Group II-VI semiconductor compound; a Group III-VI semiconductor compound; a Group III-V semiconductor compound; a Group IV-VI semiconductor compound; a Group IV element or compound; a Group semiconductor compound; or any combination thereof.

The Group II-VI semiconductor compound may include: a binary compound, such as CdS, CdSe, CdTe, ZnS, ZnSe, ZnTe, ZnO, HgS, HgSe, HgTe, MgS, MgSe, and/or the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnS, MgZnSe, ZnCdSe, and/or the like; a quaternary compound, such as CdZnSeS, CdZnSeTe, CdZnSTe, CdHgSeS, CdHgSeTe, CdHgSTe, HgZnSeS, HgZnSeTe, HgZnSTe, and/or the like; or any combination thereof.

The Group III-VI semiconductor compound may include: a binary compound, such as In₂S₃, Ga₂S₃, and/or the like; a ternary compound, such as InGaS₃, InGaSe₃, and/or the like; or any combination thereof.

The Group III-V semiconductor compound may include: a binary compound, such as GaN, GaP, GaAs, GaSb, AlN, AlP, AlAs, AlSb, InN, InP, InAs, InSb, and/or the like; a ternary compound, such as GaNP, GaNAs, GaNSb, GaPAs, GaPSb, AlNP, AlNAs, AlNSb, AlPAs, AlPSb, InAsP, InGaP, InGaAs, InAlP, InNP, InNAs, InNSb, InPAs, InPSb, GaAlNP, and/or the like; a quaternary compound, such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or the like; or any combination thereof. The Group III-V semiconductor compound may further include a Group II metal (for example, InZnP, etc.).

The Group IV-VI semiconductor compound may include: a binary compound, such as SnS, SnSe, SnTe, PbS, PbSe, PbTe, and/or the like; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; or any combination thereof.

The Group IV element or a compound including the same may include: Si and/or Ge; a binary compound, such as SiC, SiGe, and/or the like; or any combination thereof.

The Group semiconductor compound may include: a ternary compound, such as AgInS, AgInS₂, CuInS, CuInS₂, CuGaO₂, AgGaO₂, AgAlO₂, and/or the like; or any combination thereof. The Group semiconductor compound may further include a Group II element. For example, the Group semiconductor compound may include a quaternary compound such as CuInZnS.

For example, the quantum dots 151 may include a Group III-V semiconductor compound.

In one embodiment, the quantum dots 151 may include InN, InP, InAs, InSb, InAsP, InGaAs, InGaP, GaP, GaN, GaSb, GaAs, ZnS, ZnSe, ZnTe, ZnO, HgS, HgSe, HgTe, ZnSeS, ZnSeTe, ZnSTe, CdS, CdSe, CdTe, CdSeS, CdSeTe, CdSTe, HgSeS, HgSeTe, HgSTe, CdZnS, CdZnSe, CdZnTe, CdHgS, CdHgSe, CdHgTe, HgZnS, HgZnSe, HgZnTe, ZnCdSe, AgInS, AgInS₂, CuInS, CuInS₂, CuGaO₂, AgGaO₂, AgAlO₂, CulnZnS, In₂S₃, Ga₂S₃, InGaS₃, InGaSe₃, or any combination thereof.

In one or more embodiments, the quantum dots 151 may include InP and may not include cadmium (Cd), but embodiments of the present disclosure are not limited thereto.

The quantum dots 151 may have: a single structure of which the components and the composition are homogeneous; or a composite structure such as a core-shell structure, a gradient structure, and/or the like.

In one embodiment, the quantum dots 151 may each have a core-shell structure including a core including a first semiconductor crystal and a shell including a second semiconductor crystal, but embodiments of the present disclosure are not limited thereto.

The shell of the quantum dots may serve as a protective layer for maintaining semiconductor characteristics by preventing or reducing chemical degeneration of the core and/or may serve as a charging layer for imparting electrophoretic characteristics to the quantum dot. The shell may be a single layer or a multilayer. An interface between the core and the shell may have a concentration gradient in which the concentration of elements existing in the shell decreases toward the center. Examples of the shell of the quantum dot may include a metal or non-metal oxide, a semiconductor compound, or any combination thereof. For example, the shell of the quantum dot may include a metal oxide or a non-metal oxide.

For example, in the core-shell structure, a material constituting the core and a material constituting the shell may be selected from semiconductor compounds as described above.

In one embodiment, the first semiconductor crystal and the second semiconductor crystal may each independently include InN, InP, InAs, InSb, InAsP, InGaAs, InGaP, GaP, GaN, GaSb, GaAs, ZnS, ZnSe, ZnTe, ZnO, HgS, HgSe, HgTe, ZnSeS, ZnSeTe, ZnSTe, CdS, CdSe, CdTe, CdSeS, CdSeTe, CdSTe, HgSeS, HgSeTe, HgSTe, CdZnS, CdZnSe, CdZnTe, CdHgS, CdHgSe, CdHgTe, HgZnS, HgZnSe, HgZnTe, ZnCdSe, AgInS, AgInS₂, CuInS, CuInS₂, CuGaO₂, AgGaO₂, AgAlO₂, CulnZnS, In₂S₃, Ga₂S₃, InGaS₃, InGaSe₃, or any combination thereof, but embodiments of the present disclosure are not limited thereto.

In one embodiment, the first semiconductor crystal may include InN, InP, InAs, InSb, InAsP, InGaAs, InGaP, GaP, GaN, GaSb, GaAs, ZnS, ZnSe, ZnTe, HgS, HgSe, HgTe, ZnSeS, ZnSeTe, CdS, CdSe, CdTe, CdSeTe, CdZnSe, ZnCdSe, AgInS₂, CuInS, CulnZnS, or any combination thereof, and the second semiconductor crystal may include ZnS, ZnSe, ZnTe, ZnSeS, ZnSeTe, In₂S₃, Ga₂S₃, or any combination thereof, but embodiments of the present disclosure are not limited thereto.

In one or more embodiments, the quantum dots 151 may have a core-shell structure including a core including a first semiconductor crystal and a shell including a second semiconductor crystal, and the first semiconductor crystal may include a Group III-V semiconductor compound, but embodiments of the present disclosure are not limited thereto.

For example, the Group III-V semiconductor compound may include InP, but embodiments of the present disclosure are not limited thereto.

In one or more embodiments, the first semiconductor crystal may include InP and may not include cadmium (Cd), but embodiments of the present disclosure are not limited thereto. For example, the first semiconductor crystal may only include (consist of) InP.

In one or more embodiments, the quantum dots 151 may have a core-shell structure including a core including a first semiconductor crystal and a shell including a second semiconductor crystal, the first semiconductor crystal may include a Group III-V semiconductor compound, and the second semiconductor crystal may include a Group II-VI semiconductor compound. For example, the Group III-V semiconductor compound may include InP, and the Group II-VI semiconductor compound may include ZnS, ZnSe, or a combination thereof, but embodiments of the present disclosure are not limited thereto.

In one embodiment, the quantum dots 151 may further include ligands that are chemically bound to the surfaces thereof. The ligands may be chemically bound to the surfaces of the quantum dots 151 to passivate the quantum dots 151. For example, the quantum dots 151 may further include a ligand that is chemically bound to the shell.

In one embodiment, the ligands may be oleic acid, octylamine, decylamine, mercapto-propionic acid, dodecanethiol, 1-octanethiol, thionyl chloride, or any combination thereof.

The quantum dots 151 may be synthesized by utilizing various suitable methods, such as a wet chemical process, a metal organic chemical vapor deposition process (MOCVD), and/or a molecular beam epitaxy (MBE) process.

The average particle diameter of the quantum dots 151 may be in a range from about 1 nm to about 20 nm, for example, from about 1 nm to about 15 nm, or, from about 3 nm to about 15 nm. When the average particle diameter of quantum dots is within these ranges, the quantum dots may not only have characteristic behavior of quantum dots, but also have suitable (e.g., excellent) dispersibility in a pattern forming composition. Furthermore, because the average particle diameter of quantum dots are variously suitably selected within the ranges described above, emission wavelengths of the quantum dots and/or semiconducting characteristics of the quantum dots may be variously suitably changed.

When the quantum dots 151 have a core-shell structure, the ratio of the radius of the core to the thickness of the shell may be 2:8 to 8:2, for example, 3:7 to 7:3, or, 4:6 to 6:4.

The shape of the quantum dots 151 is not particularly limited to shapes generally utilized in the related art. In one embodiment, the quantum dots 151 may be spherical, pyramidal, multi-arm, or cubic nanoparticles, nanotubes, nanowires, nanofibers, nano-plate particles, and/or the like.

In one embodiment, the quantum dots 151 may be dispersed in a naturally coordinated form in a dispersion medium such as an organic solvent or a polymer resin. The dispersion medium may be any transparent medium as long as the medium is not deteriorated by light and/or does not reflect light, and the medium does not cause light absorption, while not affecting wavelength conversion performance of quantum dots. For example, the organic solvent may include at least one selected from toluene, chloroform, and ethanol, and the polymer resin may include at least one selected from epoxy, silicone, polysthylene, and acrylate.

Because quantum dots are very small in size, a quantum confinement effect may occur. The quantum confinement effect refers to a phenomenon in which, when an object becomes smaller than a few nanometers in size, a band gap of the object becomes large. Due to the quantum confinement effect, quantum dots have discontinuous band gap energy, unlike a bulk state material. In addition, quantum dots have characteristics in which a gap between energy bands varies according to the size of the quantum dots, and quantum dots of the same material may emit light having different wavelengths according to the size of the quantum dots. The smaller the quantum dots, the greater the band gap energy, and thus, the shorter the wavelength of light being emitted. By utilizing these characteristics, a size of quantum dots may be adjusted by appropriately changing growth conditions of nanocrystals to thereby obtain light in a desired wavelength range. Thus, by introducing such quantum dots into a light-emitting device, a light-emitting device having high luminance efficiency and high color purity may be embodied (e.g., obtained).

A thickness of the emission layer 150 may be in a range from about 7 nm to about 100 nm, for example, from about 15 nm to about 50 nm. Within these ranges, the light-emitting device 10 may have suitable (e.g., excellent) luminescence efficiency and/or suitable (e.g., excellent) lifespan due to control of pores that may be generated by particle arrangement in the quantum dot emission layer.

In one embodiment, the light-emitting device 10 may further include the electron transport region 160 between the emission layer 150 and the second electrode 190.

For example, the first electrode 110 may be an anode, the second electrode 190 may be a cathode, and the electron transport region 160 may be located between the emission layer 150 and the second electrode 190.

The electron transport region 160 may include at least one layer selected from a buffer layer, a hole blocking layer, an electron control layer, an electron transport layer, and an electron injection layer. An exemplary structure of the electron transport region 160 is described later.

In one embodiment, the electron transport region 160 may include ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC₆₀BM, PC₇₀BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof.

For example, the electron transport region 160 may include an electron transport layer, and the electron transport layer may include ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC₆₀BM, PC₇₀BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof, but embodiments of the present disclosure are not limited thereto.

In one embodiment, a material included in the electron transport region 160 may be nanoparticles, for example, nanoparticles having an average diameter of about 3 nm to about 15 nm.

In one embodiment, the electron transport layer may have a thickness of about 20 nm to about 150 nm. Accordingly, in a process of forming the second electrode 190, damage to the lower emission layer 150 may be prevented or reduced.

In one embodiment, the first electrode 110 may be an anode which is a hole injection electrode, and holes provided from the first electrode 110 may be directly injected to the emission layer 150 or may be injected to the emission layer 150 due to (e.g., through) a tunneling effect.

When voltage is applied between the first electrode 110 and the second electrode 190 of the light-emitting device 10, holes may be injected from the first electrode 110 to the emission layer 150 due to an electric field across both ends of the electron sink layer 140.

In one or more embodiments, the first electrode 110 is an anode which is a hole injection electrode, the hole transport region 130 may include a hole transport layer, the hole transport layer may directly contact the electron sink layer 140, and holes provided from the first electrode 110 may be directly injected to the emission layer 150 or may be injected to the emission layer 150 due to a tunneling effect.

### First Electrode 110

In FIG. 1, a substrate may be additionally located under the first electrode 110 or above the second electrode 190. The substrate may be a glass substrate or a plastic substrate, each having suitable (e.g., excellent) mechanical strength, thermal stability, transparency, surface smoothness, ease of handling, and/or water resistance.

For example, in a case of a top-emission light-emitting device 10 that emits light in a direction opposite to a substrate, the substrate is not necessarily transparent and may be opaque or semi-transparent. In this case, a metal may be utilized to form the substrate. When forming the substrate by utilizing a metal, the substrate may include at least one selected from iron, chromium, manganese, nickel, titanium, molybdenum, stainless steel (SUS), iron-nickel alloy (e.g., Invar® alloy), nickel-chromium based alloy (e.g., Inconel® alloy), and nickel-cobalt ferrous alloy (e.g., Kovar® alloy), but embodiments of the present disclosure are not limited thereto. In one embodiment, the substrate may include carbon, and/or the metal described above.

In addition, in one embodiment, a buffer layer, a thin-film transistor, an organic insulating layer, and/or the like may be further located between the substrate and the first electrode 110.

The first electrode 110 may be formed by depositing or sputtering a material for forming the first electrode 110 on the substrate. The first electrode 110 may be a reflective electrode, a semi-transmissive electrode, or a transmissive electrode. When the first electrode 110 is a transmissive electrode, a material for forming the first electrode 110 may be selected from indium tin oxide (ITO), indium zinc oxide (IZO), tin oxide (SnO₂), zinc oxide (ZnO), gallium zinc oxide (GZO), aluminum zinc oxide (AZO), InZnSnOₓ (IZSO), ZnSnOₓ (ZSO), graphene, PEDOT:PSS, carbon nanotube, silver nanowire (Ag nanowire), gold nanowire (Au nanowire), metal mesh, and any combination thereof, but embodiments of the present disclosure are not limited thereto. In one or more embodiments, when the first electrode 110 is a semi-transmissive electrode or a reflective electrode, a material for forming the first electrode 110 may be selected from magnesium (Mg), silver (Ag), aluminum (Al), aluminum-lithium (Al—Li), calcium (Ca), magnesium-indium (Mg—In), magnesium-silver (Mg—Ag), and any combination thereof, but embodiments of the present disclosure are not limited thereto.

The first electrode 110 may have a single-layered structure or a multi-layered structure including two or more layers. For example, the first electrode 110 may have a three-layered structure of ITO/Ag/ITO, but the structure of the first electrode 110 is not limited thereto.

### Hole Transport Region 130

The hole transport region 130 may have i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure having a plurality of layers including (e.g., consisting of) a plurality of different materials.

The hole transport region 130 may include at least one layer selected from a hole injection layer, a hole transport layer, an emission auxiliary layer, and an electron blocking layer.

For example, the hole transport region 130 may have a single-layered structure including (e.g., consisting of) a single layer including (e.g., consisting of) a plurality of different materials, or a multi-layered structure having a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein for each structure, constituting layers are sequentially stacked from the first electrode 110 in the respective stated order, but the structure of the hole transport region 130 is not limited thereto.

The hole transport region 130 may include an amorphous inorganic material and/or organic material. The inorganic material may include NiO, MoO₃, Cr₂O₃, and/or Bi₂O₃. In addition, the inorganic material may be a p-type inorganic semiconductor and may include: a p-type inorganic semiconductor in which a non-metal (such as O, S, Se and/or Te) is doped with iodide, bromide and/or chloride of Cu, Ag and/or Au; a p-type inorganic semiconductor in which a metal (such as Cu, Ag and/or Au) and a non-metal element (such as N, P, As, Sb and/or Bi) are doped with a compound including Zn; or an intrinsic p-type inorganic semiconductor such as ZnTe.

The organic material may include at least one selected from m-MTDATA, TDATA, 2-TNATA, NPB(NPD), 8-NPB, TPD, spiro-TPD, spiro-NPB, methylated-NPB, DNTPD, TAPC, HMTPD, 4,4′,4″-tris(N-carbazolyl)triphenylamine (TCTA), poly(N,N′-bis-4-butylphenyl-N,N′-bisphenyl)benzidine (Poly-TPD), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), a compound represented by Formula 201, and a compound represented by Formula 202:

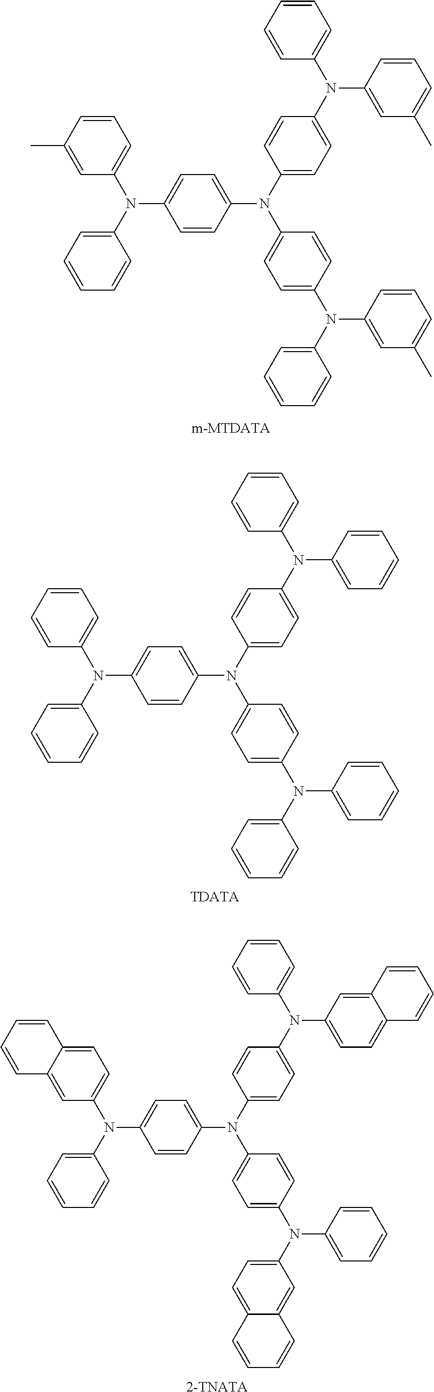

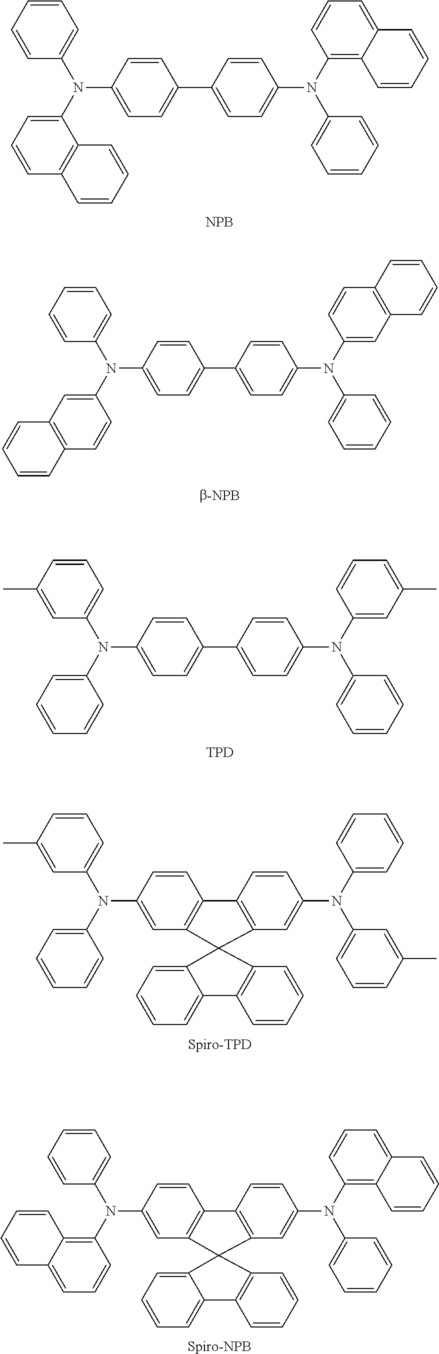

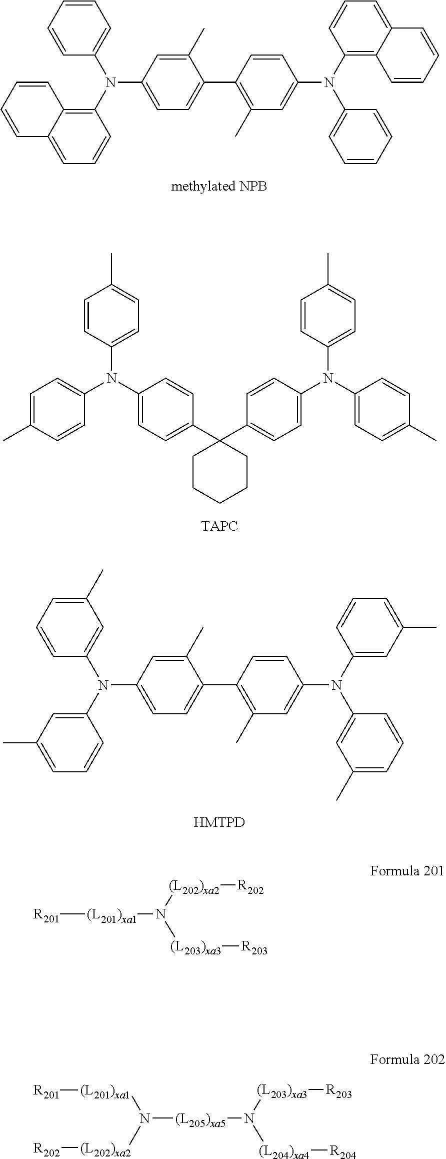

In Formulae 201 and 202,

L₂₀₁ to L₂₀₄ may each independently be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

L₂₀₅ may be selected from *—O—*′, *—S—*′, *—N(Q₂₀₁)-*′, a substituted or unsubstituted C₁-C₂₀ alkylene group, a substituted or unsubstituted C₂-C₂₀ alkenylene group, a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xa1 to xa4 may each independently be an integer from 0 to 3,

xa5 may be an integer from 1 to 10, and

R₂₀₁ to R₂₀₄ and Q₂₀₁ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

For example, in Formula 202, R₂₀₁ and R₂₀₂ may optionally be linked to each other via a single bond, a dimethyl-methylene group, or a diphenyl-methylene group, and R₂₀₃ and R₂₀₄ may optionally be linked to each other via a single bond, a dimethyl-methylene group, or a diphenyl-methylene group.

The hole transport region 130 may include at least one compound selected from Compounds HT1 to HT48, but embodiments of the present disclosure are not limited thereto:

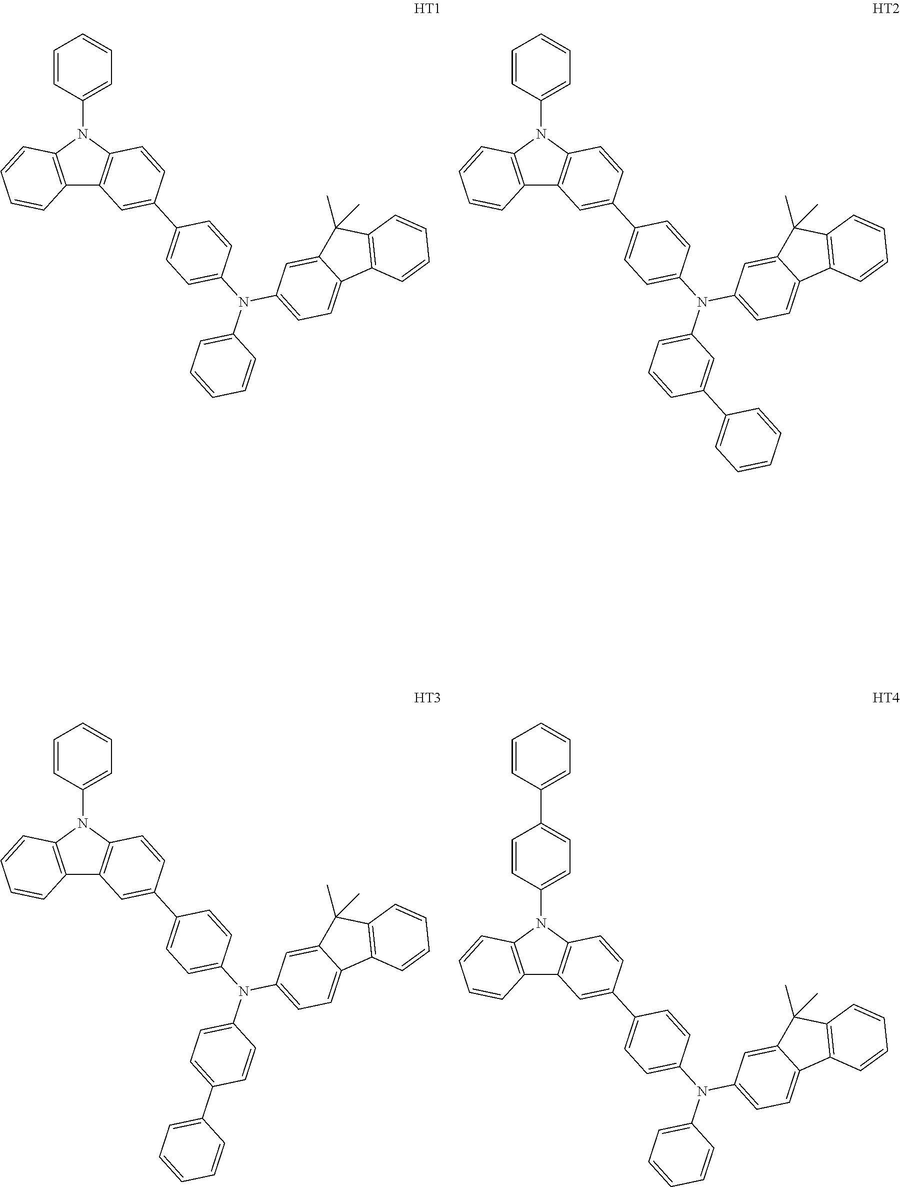

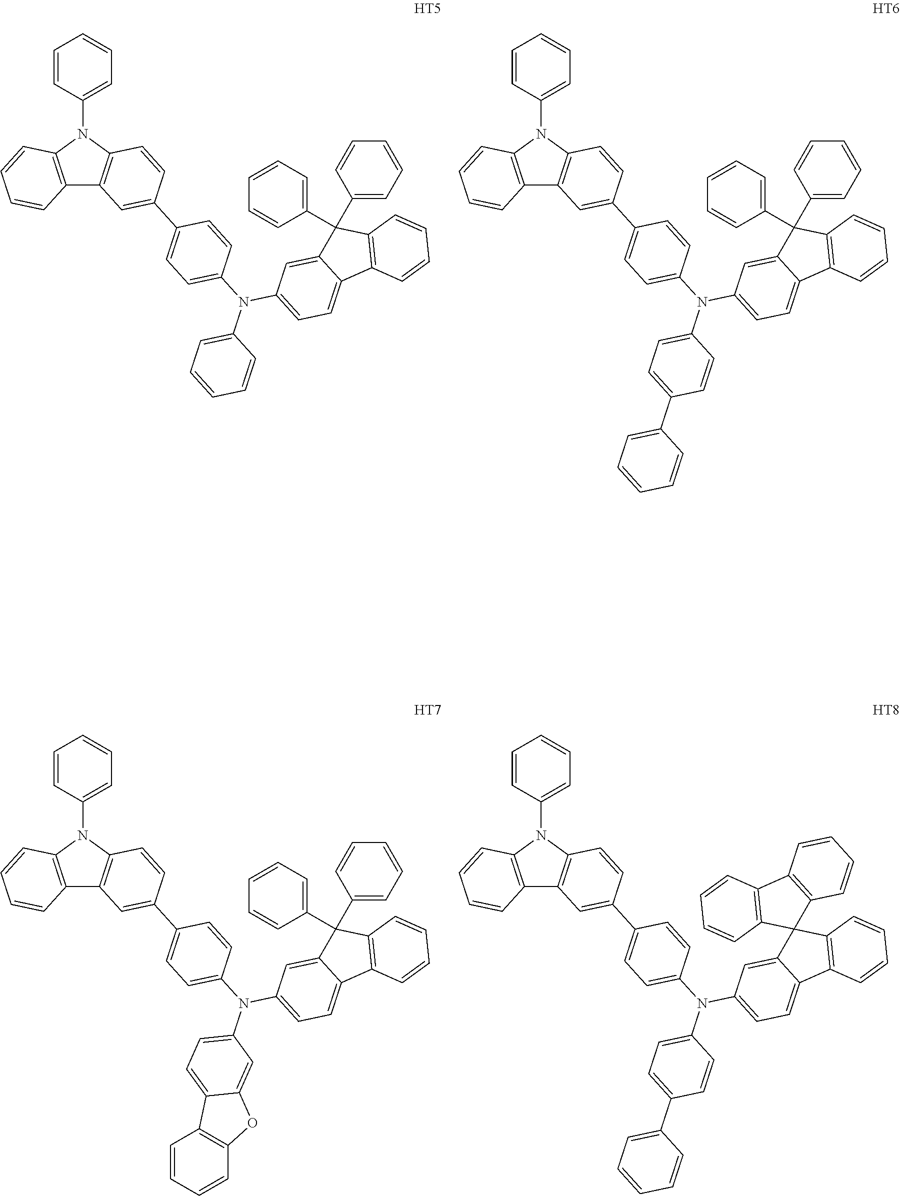 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

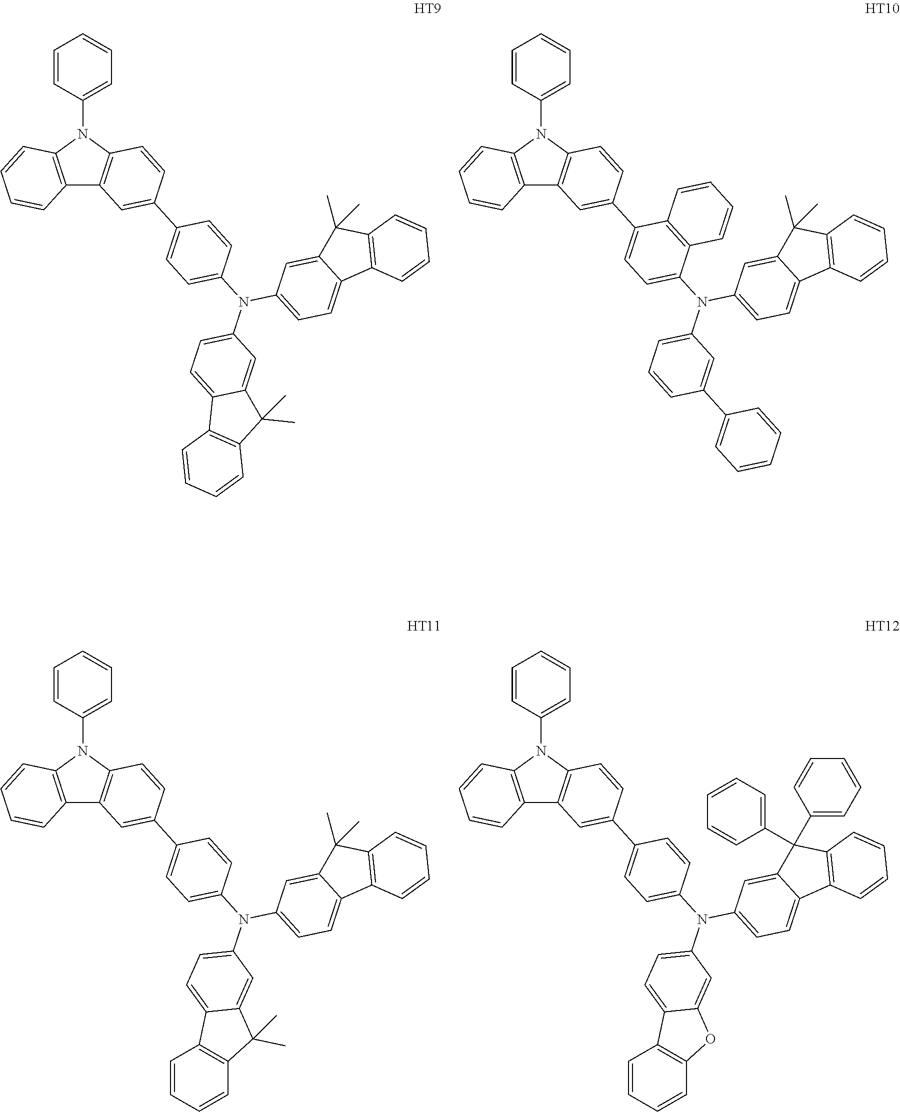 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1]

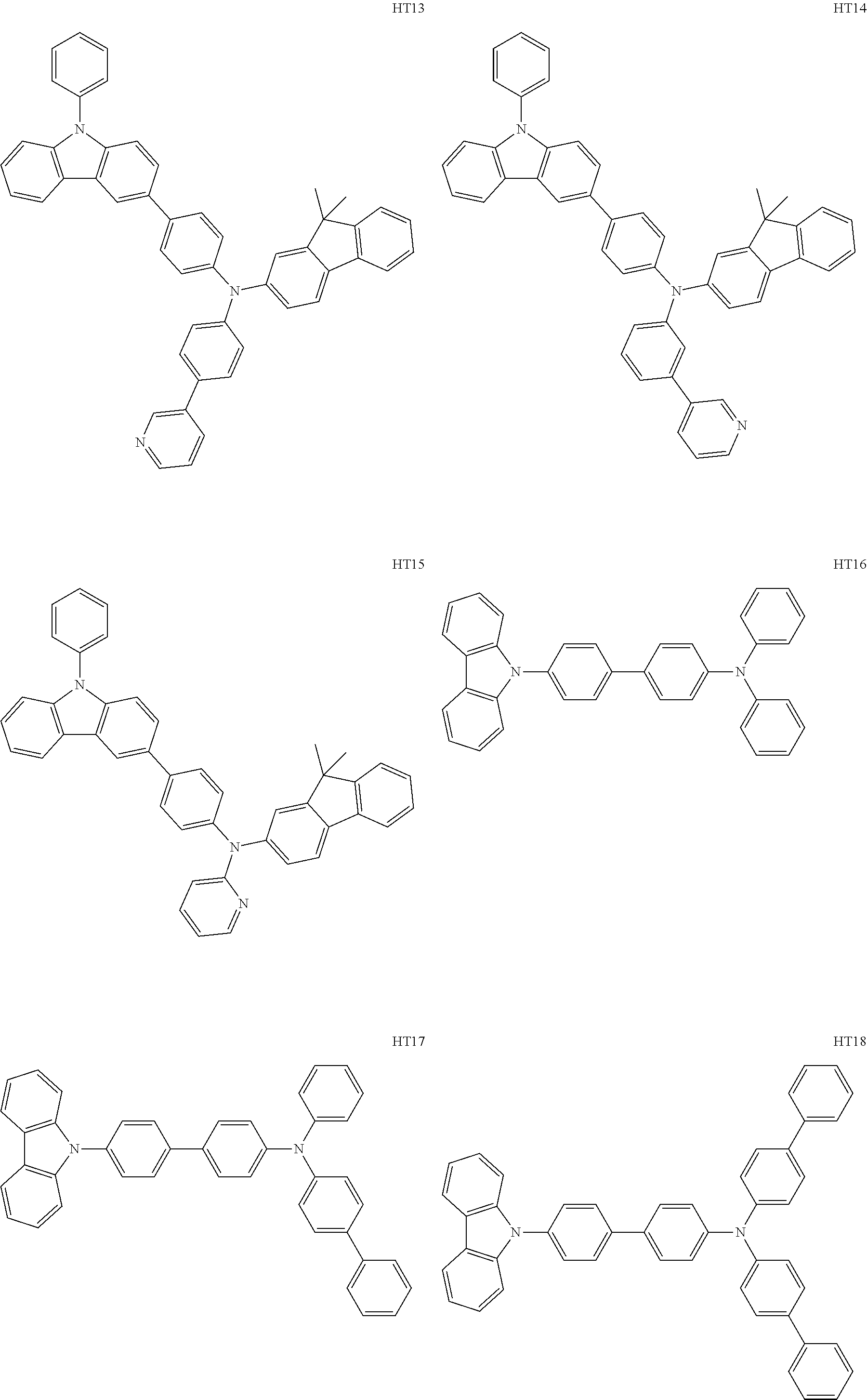

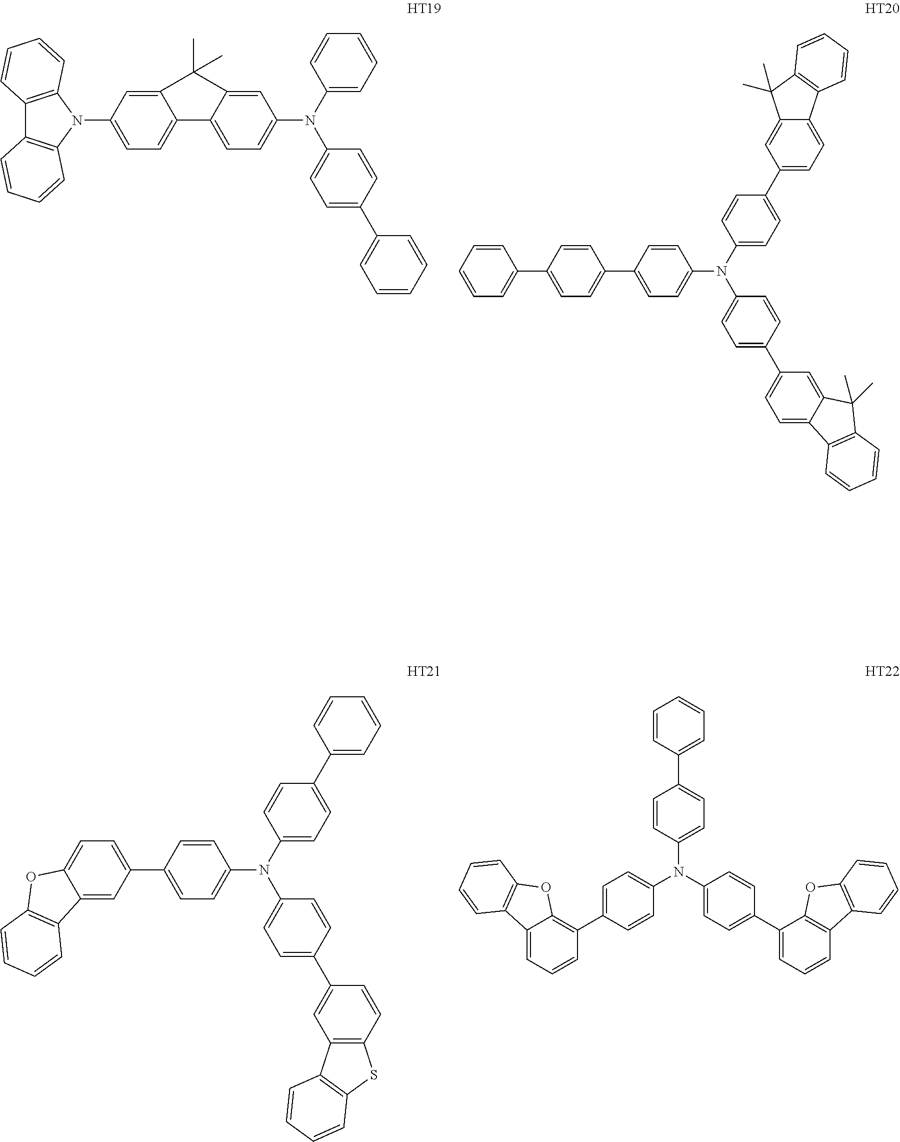

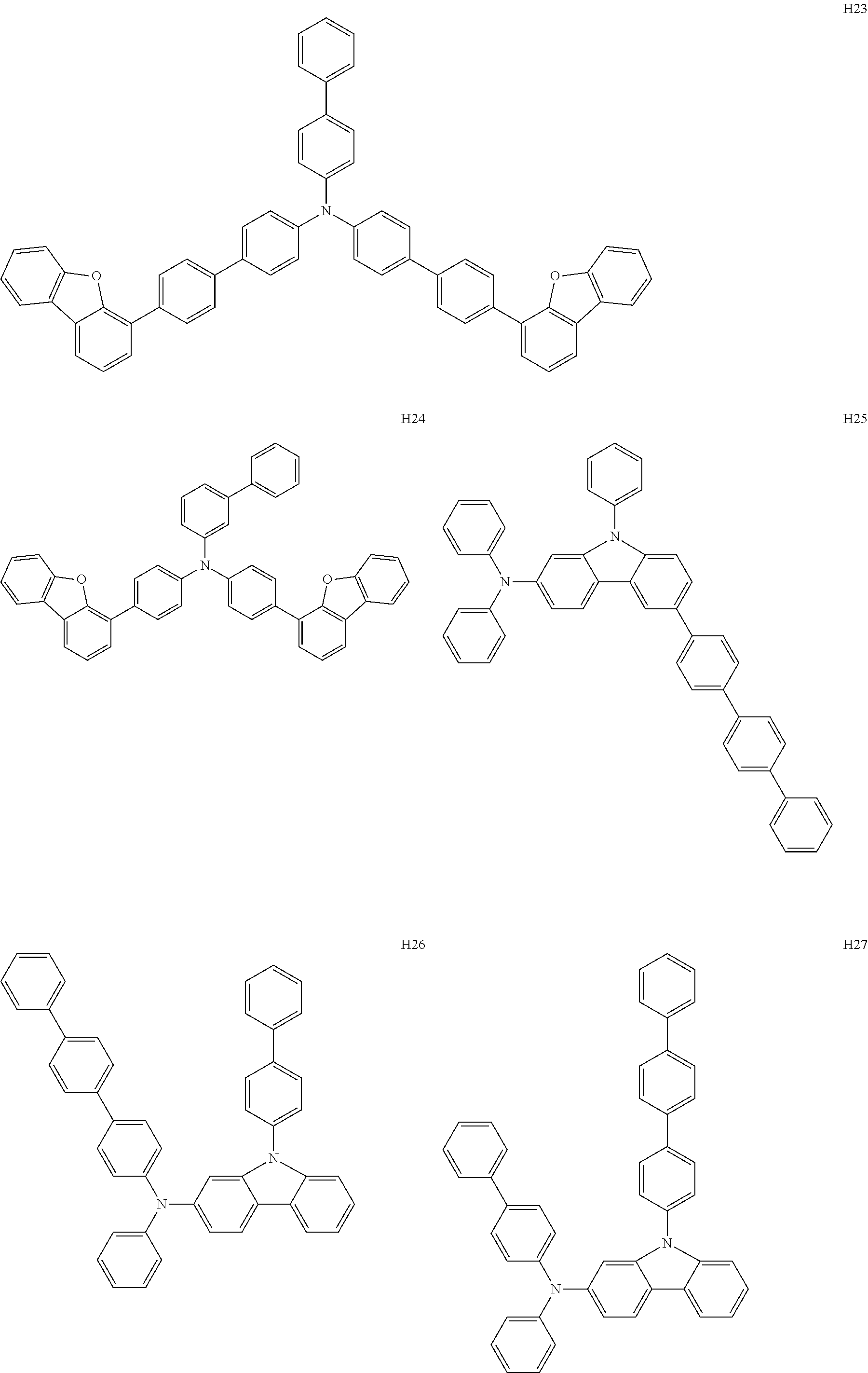 [SMILES: c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

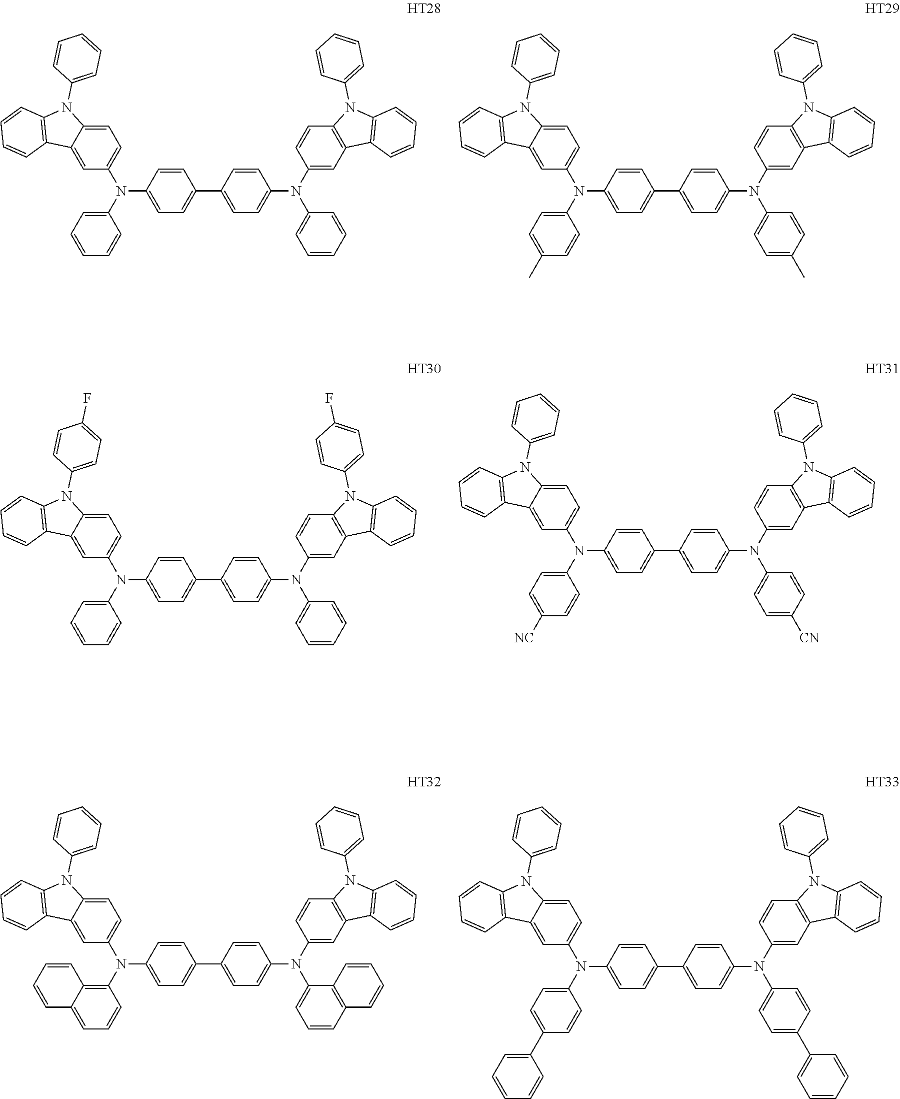

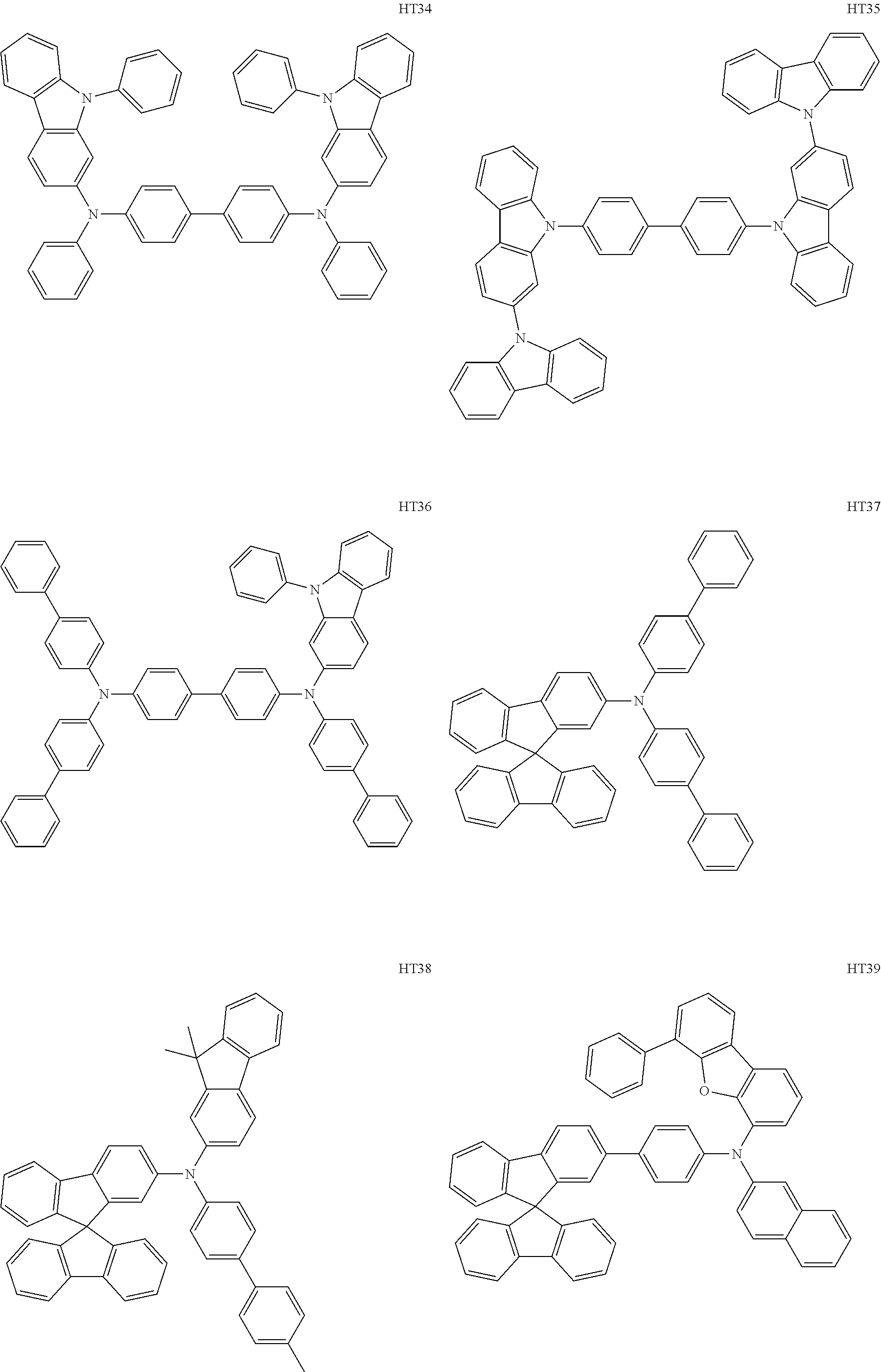

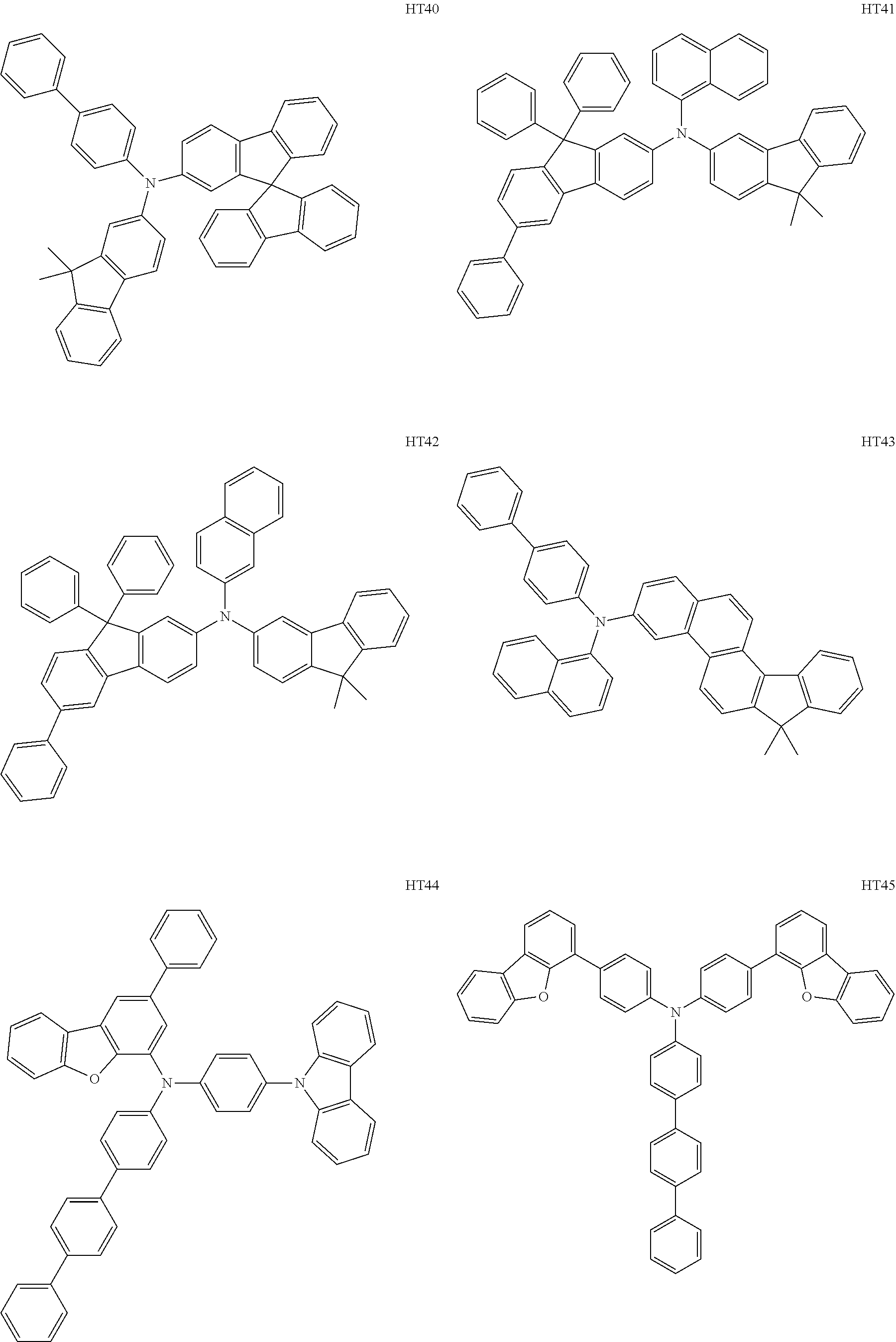

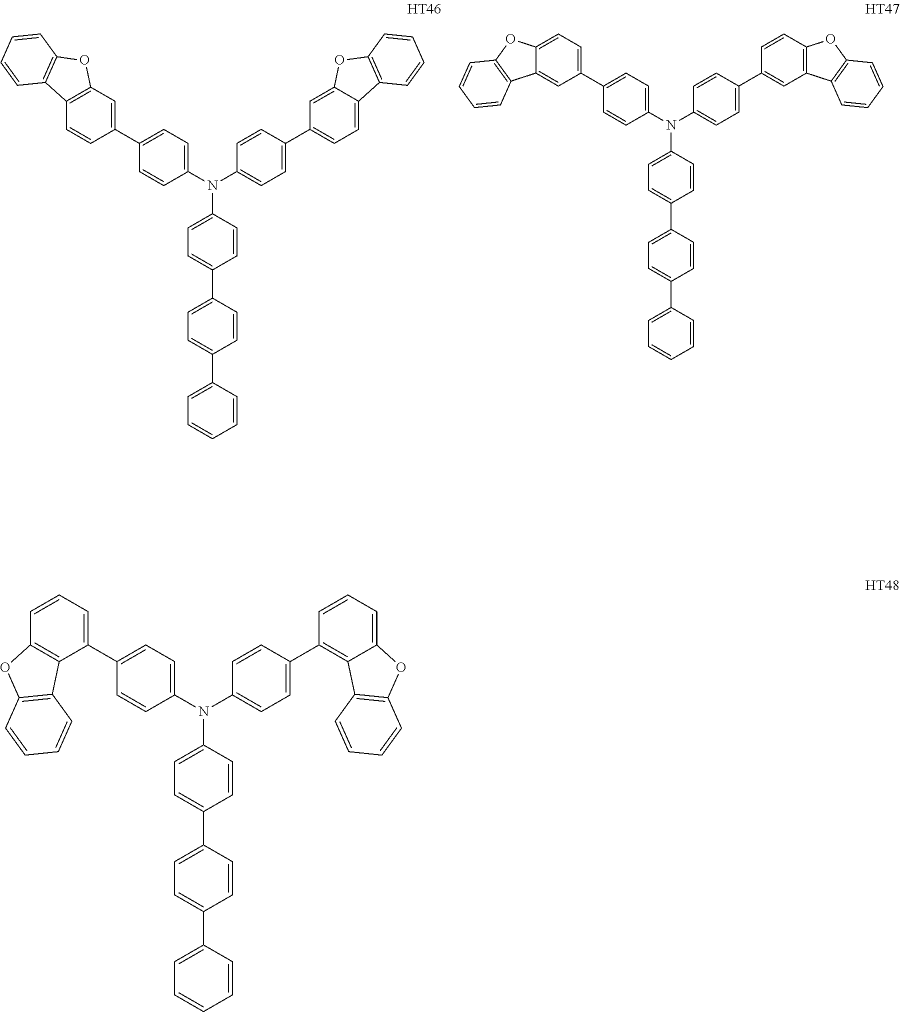 [SMILES: c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1 ; c1ccc(-c2ccc(-c3ccc(N(c4ccc(-c5ccc6oc7ccccc7c6c5)cc4)c4ccc(-c5ccc6oc7ccccc7c6c5)cc4)cc3)cc2)cc1 ; c1ccc(-c2ccc(-c3ccc(N(c4ccc(-c5cccc6oc7ccccc7c56)cc4)c4ccc(-c5cccc6oc7ccccc7c56)cc4)cc3)cc2)cc1]

A thickness of the hole transport region 130 may be in a range of about 100 Å to about 10,000 Å, for example, about 100 Å to about 1,000 Å. When the hole transport region 130 includes at least one of a hole injection layer and a hole transport layer, a thickness of the hole injection layer may be from about 100 Å to about 9,000 Å, for example, from about 100 Å to about 1,000 Å, and a thickness of the hole transport layer may be from about 50 Å to about 2,000 Å, for example, from about 100 Å to about 1,500 Å. When the thicknesses of the hole transport region 130, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to the wavelength of light emitted by an emission layer, and the electron blocking layer may block the flow of electrons from the electron transport region 160. The emission auxiliary layer and the electron blocking layer may include the materials as described above.

### P-Dopant

The hole transport region may further include, in addition to the materials described above, a charge-generation material for the improvement of conductive properties. The charge-generation material may be homogeneously or non-homogeneously dispersed in the hole transport region.

The charge-generation material may be, for example, a p-dopant.

In one embodiment, a lowest unoccupied molecular orbital (LUMO) energy level of the p-dopant may be −3.5 eV or less.

The p-dopant may include at least one selected from a quinone derivative, a metal oxide, and a cyano group-containing compound, but embodiments of the present disclosure are not limited thereto.

In one embodiment, the p-dopant may include at least one selected from:

a quinone derivative, such as tetracyanoquinodimethane (TCNQ) or 2,3,5,6-tetrafluoro-7,7,8,8-tetracyanoquinodimethane (F4-TCNQ);

a metal oxide, such as tungsten oxide and/or molybdenum oxide;

1,4,5,8,9,12-hexaazatriphenylene-hexacarbonitrile (HAT-CN); and

a compound represented by Formula 221 below,

but embodiments of the present disclosure are not limited thereto:

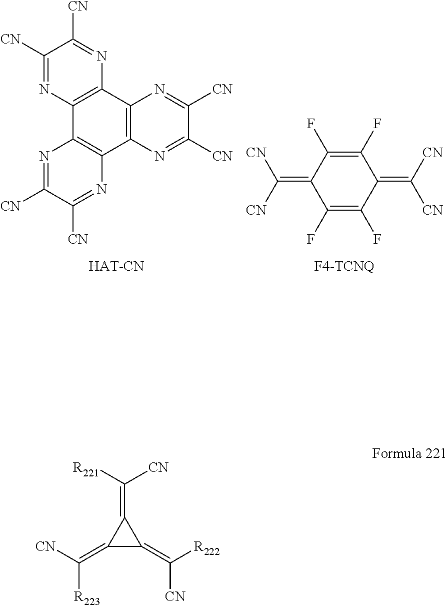

In Formula 221,

R₂₂₁ to R₂₂₃ may each independently be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, wherein at least one of R₂₂₁ to R₂₂₃ may have at least one substituent selected from a cyano group, —F, —Cl, —Br, —I, a C₁-C₂₀ alkyl group substituted with —F, a C₁-C₂₀ alkyl group substituted with —Cl, a C₁-C₂₀ alkyl group substituted with —Br, and a C₁-C₂₀ alkyl group substituted with —I.

### Emission Layer 150

The emission layer 150 may have a quantum dot single layered structure or a structure in which two or more quantum dot layers are stacked. For example, the emission layer 150 may have a quantum dot single layered structure or a structure in which 2 to 100 quantum dot layers are stacked.

The emission layer 150 includes the quantum dots 151.

The emission layer 150 may be formed by applying a composition for forming the emission layer 150 onto the electron sink layer 140, wherein the composition includes quantum dots 151 dispersed in a solvent, and volatilizing (e.g., evaporating) the solvent.

The composition for forming an emission layer may be applied by utilizing one or more methods selected from spin coating, casting, micro-gravure coating, gravure coating, bar coating, roll coating, wire bar coating, dip coating, spray coating, screen printing, flexographic printing, offset printing, and ink-jet printing.

As the solvent, water, hexane, chloroform, toluene, and/or the like may be utilized, but the solvent is not particularly limited thereto as long as it can dissolve the material utilized to form the emission layer.

When the light-emitting device 10 is a full color light-emitting device, the emission layer 150 may include an emission layer that emits light of different colors for each sub-pixel.

For example, the emission layer 150 may be patterned into a first-color emission layer, a second-color emission layer, and a third-color emission layer, for each sub-pixel. In this case, at least one emission layer from among the emission layers described above may necessarily include quantum dots. For example, the first-color emission layer may be a quantum dot emission layer including quantum dots, and the second-color emission layer and the third-color emission layer may each be an organic emission layer including an organic compound. Here, the first color to the third color may be different from one another, and in more detail, the first color to the third color may have different maximum emission wavelengths. The first color to the third color may be combined with each other to thereby provide a white color.

In one embodiment, the emission layer 150 may further include a fourth-color emission layer, at least one emission layer from among the first-color to fourth-color emission layers may be a quantum dot emission layer including quantum dots, the other emission layers may each be an organic emission layer including an organic compound, and various suitable modifications are possible. Here, the first color to the fourth color may be different from each other, and in more detail, the first color to the fourth color may have different maximum emission wavelength. The first color to the fourth color may be combined with each other to thereby provide a white color.

In one or more embodiments, the light-emitting device 10 may have a stacked structure in which two or more emission layers emitting the same or different colors are in contact with or spaced apart from each other. At least one emission layer from among the two or more emission layers may be a quantum dot emission layer including quantum dots, the other emission layers may be an organic emission layer including an organic compound, and various suitable modifications are possible. In one embodiment, the light-emitting device 10 may include a first-color emission layer and a second-color emission layer, wherein the first color and the second color may be identical to or different from each other. In one embodiment, both the first color and the second color may be blue.

The emission layer 150 may further include at least one selected from an organic compound and a semiconductor compound, in addition to quantum dots, but embodiments of the present disclosure are not limited thereto.

In one embodiment, the semiconductor compound may be an organic perovskite and/or an inorganic perovskite.

In one embodiment, the organic compound may include a host and a dopant. The host and the dopant may respectively include materials (e.g., a host and a dopant) that are generally utilized in organic light-emitting devices.

### Electron Transport Region 160

The electron transport region 160 may have i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure having a plurality of layers including (e.g., consisting of) a plurality of different materials.

The electron transport region 160 may include at least one layer selected from a buffer layer, a hole blocking layer, an electron control layer, an electron transport layer, and an electron injection layer, but embodiments of the present disclosure are not limited thereto.

For example, the electron transport region 160 may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein for each structure, constituting layers are sequentially stacked from the emission layer in the respective stated order. However, embodiments of the structure of the electron transport region are not limited thereto.

The electron transport region 160 may include a conductive metal oxide. For example, the electron transport region 160 may include ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC₆₀BM, PC₇₀BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof.

The organic material may include a suitable (e.g., known) compound having electron transport characteristics, such as 2,9-dimethyl-4,7-diphenyl-1,10-phenanthroline (BCP), 4,7-Diphenyl-1,10-phenanthroline (Bphen), Alq₃, BAlq, 3-(biphenyl-4-yl)-5-(4-tert-butylphenyl)-4-phenyl-4H-1,2,4-triazole (TAZ), and/or NTAZ.

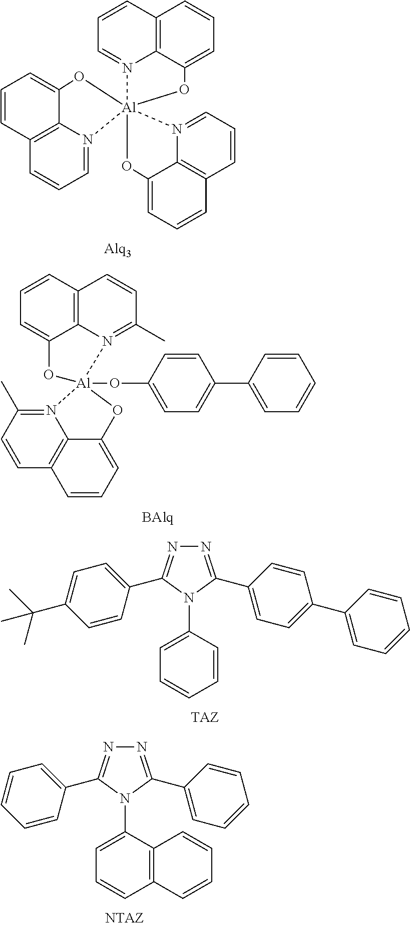

In addition, the organic material may include a metal-free compound including at least one π-electron-deficient nitrogen-containing ring.

The term “π-electron-deficient nitrogen-containing ring” refers to a C₁-C₆₀ heterocyclic group having at least one *—N=*′ moiety as a ring-forming moiety.

For example, the “π-electron-deficient nitrogen-containing ring” may be i) a 5-membered to 7-membered heteromonocyclic group having at least one *—N=*′ moiety, ii) a heteropolycyclic group in which two or more 5-membered to 7-membered heteromonocyclic groups each having at least one *—N=*′ moiety are condensed with each other, or iii) a heteropolycyclic group in which at least one of 5-membered to 7-membered heteromonocyclic groups, each having at least one *—N=*′ moiety, is condensed with at least one C₅-C₆₀ carbocyclic group.

Non-limiting examples of the π-electron-deficient nitrogen-containing ring include an imidazole ring, a pyrazole ring, a thiazole ring, an isothiazole ring, an oxazole ring, an isoxazole ring, a pyridine ring, a pyrazine ring, a pyrimidine ring, a pyridazine ring, an indazole ring, a purine ring, a quinoline ring, an isoquinoline ring, a benzoquinoline ring, a phthalazine ring, a naphthyridine ring, a quinoxaline ring, a quinazoline ring, a cinnoline ring, a phenanthridine ring, an acridine ring, a phenanthroline ring, a phenazine ring, a benzimidazole ring, an isobenzothiazole ring, a benzoxazole ring, an isobenzoxazole ring, a triazole ring, a tetrazole ring, an oxadiazole ring, a triazine ring, a thiadiazole ring, an imidazopyridine ring, an imidazopyrimidine ring, and an azacarbazole ring.

For example, the electron transport region 160 may include a compound represented by Formula 601 below:

[Ar₆₀₁]ₓₑ₁₁-[(L₆₀₁)ₓₑ₁-R₆₀₁])ₓₑ₂₁ Formula 601

In Formula 601,

Ar₆₀₁ may be a substituted or unsubstituted C₅-C₆₀ carbocyclic group or a substituted or unsubstituted C₁-C₆₀ heterocyclic group,

xe11 may be 1, 2, or 3,

L₆₀₁ may be selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group,

xe1 may be an integer from 0 to 5,

R₆₀₁ may be selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₆₀₁)(Q₆₀₂)(Q₆₀₃), —C(═O)(Q₆₀₁), —S(═O)₂(Q₆₀₁), and —P(═O)(Q₆₀₁)(Q₆₀₂), Q₆₀₁ to Q₆₀₃ may each independently be a C₁-C₁₀ alkyl group, a C₁-C₁₀ alkoxy group, a phenyl group, a biphenyl group, a terphenyl group, or a naphthyl group, and

xe21 may be an integer from 1 to 5.

In one embodiment, at least one of Ar₆₀₁(s) in the number of xe11 and R₆₀₁(s) in the number of xe21 may include the π-electron-deficient nitrogen-containing ring.

In one embodiment, Ar₆₀₁ in Formula 601 may be selected from:

a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, and an azacarbazole group; and

a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a carbazole group, an imidazole group, a pyrazole group, a thiazole group, an isothiazole group, an oxazole group, an isoxazole group, a pyridine group, a pyrazine group, a pyrimidine group, a pyridazine group, an indazole group, a purine group, a quinoline group, an isoquinoline group, a benzoquinoline group, a phthalazine group, a naphthyridine group, a quinoxaline group, a quinazoline group, a cinnoline group, a phenanthridine group, an acridine group, a phenanthroline group, a phenazine group, a benzimidazole group, an isobenzothiazole group, a benzoxazole group, an isobenzoxazole group, a triazole group, a tetrazole group, an oxadiazole group, a triazine group, a thiadiazole group, an imidazopyridine group, an imidazopyrimidine group, and an azacarbazole group, each substituted with at least one selected from deuterium, —F, —Cl, —Br, —I, a hydroxyl group, a cyano group, a nitro group, an amidino group, a hydrazino group, a hydrazone group, a C₁-C₂₀ alkyl group, a C₁-C₂₀ alkoxy group, a phenyl group, a biphenyl group, a terphenyl group, a naphthyl group, —Si(Q₃₁)(Q₃₂)(Q₃₃), —S(═O)₂(Q₃₁), and —P(═O)(Q₃₁)(Q₃₂), wherein Q₃₁ to Q₃₃ may each independently be selected from a C₁-C₁₀ alkyl group, a C₁-C₁₀ alkoxy group, a phenyl group, a biphenyl group, a terphenyl group, and a naphthyl group.

When xe11 in Formula 601 is 2 or more, two or more of Ar₆₀₁(s) may be linked to each other via a single bond.

In one or more embodiments, Ar₆₀₁ in Formula 601 may be an anthracene group.

In one or more embodiments, a compound represented by Formula 601 may be represented by Formula 601-1 below:

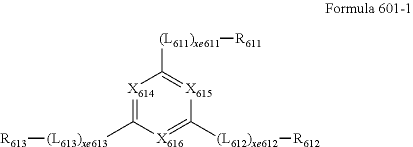

In Formula 601-1,

X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,

L₆₁₁ to L₆₁₃ may each independently be the same as described in connection with L₆₀₁,

xe611 to xe613 may each independently be the same as described in connection with xe1₇

R₆₁₁ to R₆₁₃ may each independently be the same as described in connection with R₆₀₁, and

R₆₁₄ to R₆₁₆ may each independently be selected from hydrogen, deuterium, —F, —Cl, —Br, —I, a hydroxyl group, a cyano group, a nitro group, an amidino group, a hydrazino group, a hydrazone group, a C₁-C₂₀ alkyl group, a C₁-C₂₀ alkoxy group, a phenyl group, a biphenyl group, a terphenyl group, and a naphthyl group.

In one embodiment, L₆₀₁ and L₆₁₁ to L₆₁₃ in Formulae 601 and 601-1 may each independently be selected from:

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, a pyridinylene group, an imidazolylene group, a pyrazolylene group, a thiazolylene group, an isothiazolylene group, an oxazolylene group, an isoxazolylene group, a thiadiazolylene group, an oxadiazolylene group, a pyrazinylene group, a pyrimidinylene group, a pyridazinylene group, a triazinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, an isobenzothiazolylene group, a benzoxazolylene group, an isobenzoxazolylene group, a triazolylene group, a tetrazolylene group, an imidazopyridinylene group, an imidazopyrimidinylene group, and an azacarbazolylene group; and

a phenylene group, a naphthylene group, a fluorenylene group, a spiro-bifluorenylene group, a benzofluorenylene group, a dibenzofluorenylene group, a phenanthrenylene group, an anthracenylene group, a fluoranthenylene group, a triphenylenylene group, a pyrenylene group, a chrysenylene group, a perylenylene group, a pentaphenylene group, a hexacenylene group, a pentacenylene group, a thiophenylene group, a furanylene group, a carbazolylene group, an indolylene group, an isoindolylene group, a benzofuranylene group, a benzothiophenylene group, a dibenzofuranylene group, a dibenzothiophenylene group, a benzocarbazolylene group, a dibenzocarbazolylene group, a dibenzosilolylene group, a pyridinylene group, an imidazolylene group, a pyrazolylene group, a thiazolylene group, an isothiazolylene group, an oxazolylene group, an isoxazolylene group, a thiadiazolylene group, an oxadiazolylene group, a pyrazinylene group, a pyrimidinylene group, a pyridazinylene group, a triazinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a phenanthridinylene group, an acridinylene group, a phenanthrolinylene group, a phenazinylene group, a benzimidazolylene group, an isobenzothiazolylene group, a benzoxazolylene group, an isobenzoxazolylene group, a triazolylene group, a tetrazolylene group, an imidazopyridinylene group, an imidazopyrimidinylene group, and an azacarbazolylene group, each substituted with at least one selected from deuterium, —F, —Cl, —Br, —I, a hydroxyl group, a cyano group, a nitro group, an amidino group, a hydrazino group, a hydrazone group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group,

but embodiments of the present disclosure are not limited thereto.

In one or more embodiments, xe1 and xe611 to xe613 in Formulae 601 and 601-1 may each independently be 0, 1, or 2.

In one or more embodiments, R₆₀₁ and R₆₁₁ to R₆₁₃ in Formulae 601 and 601-1 may each independently be selected from:

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group;

a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group, each substituted with at least one selected from deuterium, —F, —Cl, —Br, —I, a hydroxyl group, a cyano group, a nitro group, an amidino group, a hydrazino group, a hydrazone group, a C₁-C₂₀ alkyl group, a C₁-C₂₀ alkoxy group, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a perylenyl group, a pentaphenyl group, a hexacenyl group, a pentacenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, a pyridinyl group, an imidazolyl group, a pyrazolyl group, a thiazolyl group, an isothiazolyl group, an oxazolyl group, an isoxazolyl group, a thiadiazolyl group, an oxadiazolyl group, a pyrazinyl group, a pyrimidinyl group, a pyridazinyl group, a triazinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a phenanthridinyl group, an acridinyl group, a phenanthrolinyl group, a phenazinyl group, a benzimidazolyl group, an isobenzothiazolyl group, a benzoxazolyl group, an isobenzoxazolyl group, a triazolyl group, a tetrazolyl group, an imidazopyridinyl group, an imidazopyrimidinyl group, and an azacarbazolyl group; and

—S(═O)₂((Q₆₀₁), and —P(═O)(Q₆₀₁)(Q₆₀₂),

wherein Q₆₀₁ and Q₆₀₂ are each independently the same as described above.

The electron transport region 160 may include at least one compound selected from Compounds ET1 to ET36, but embodiments of the present disclosure are not limited thereto:

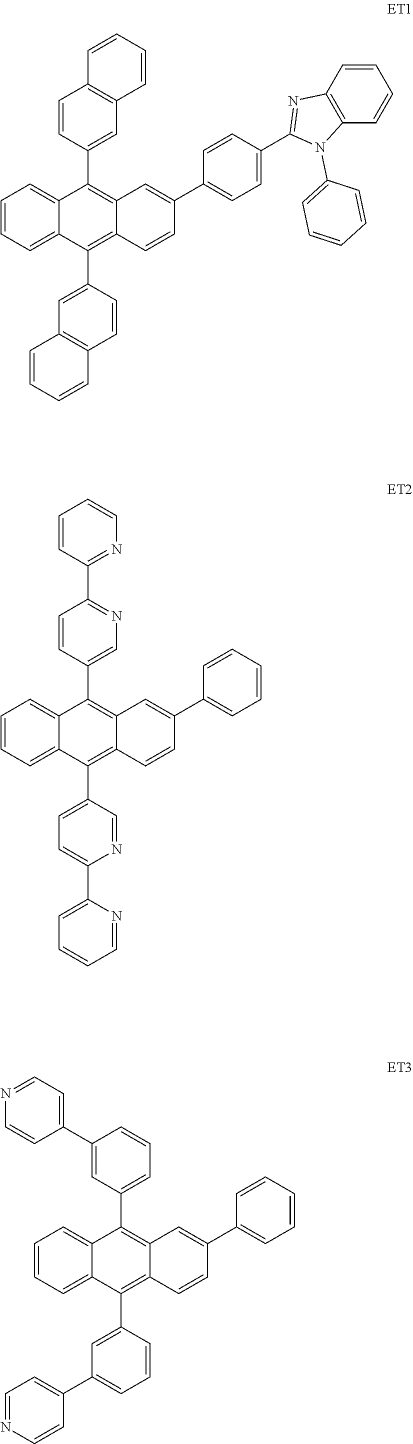 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

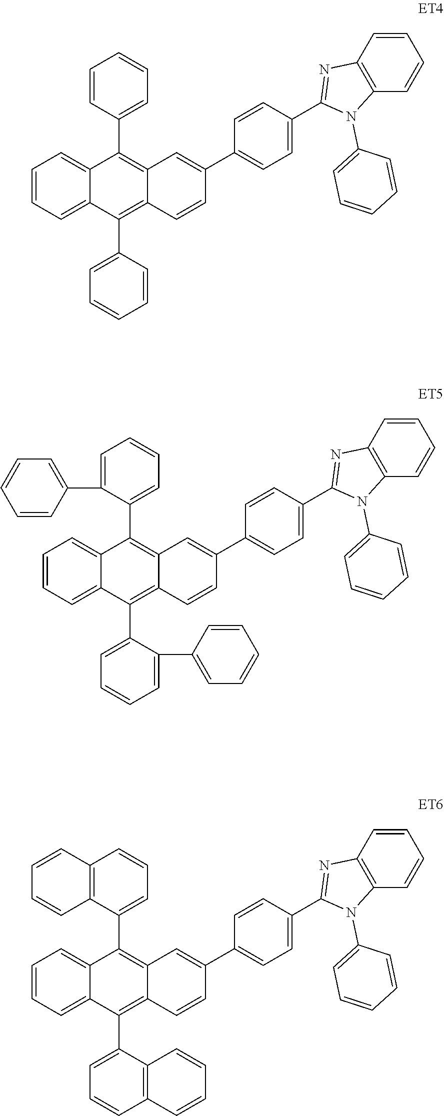 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

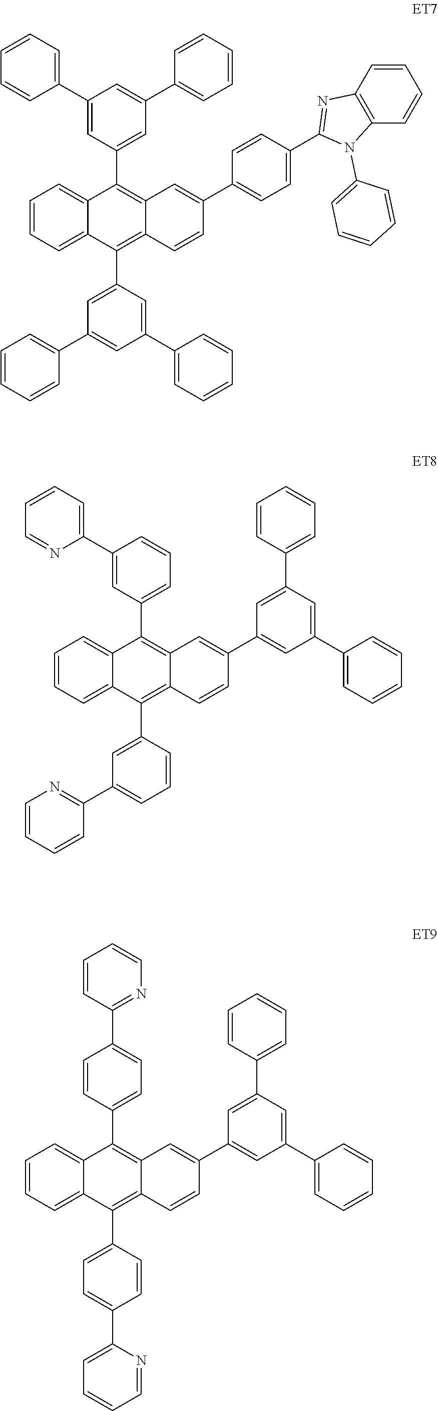 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

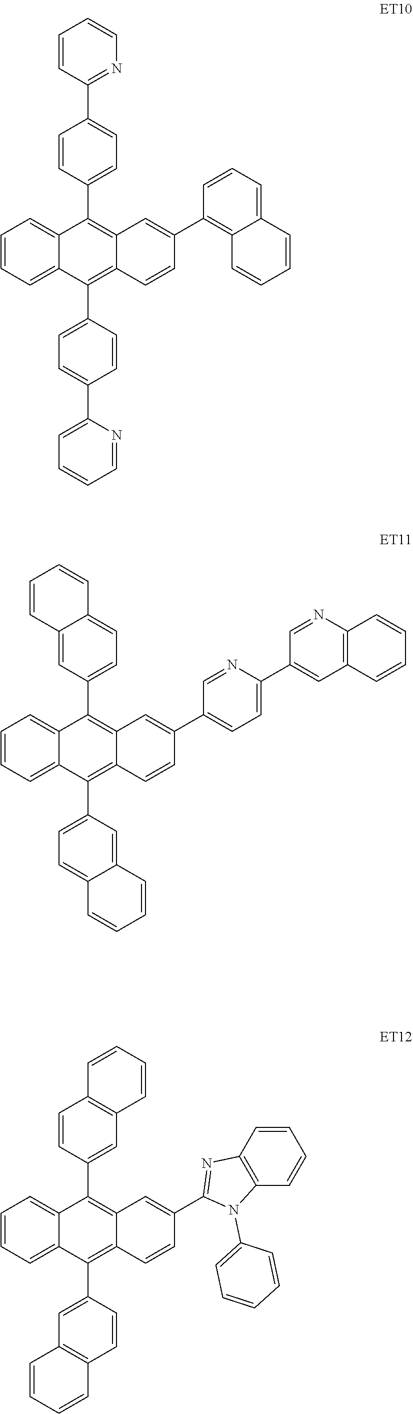 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

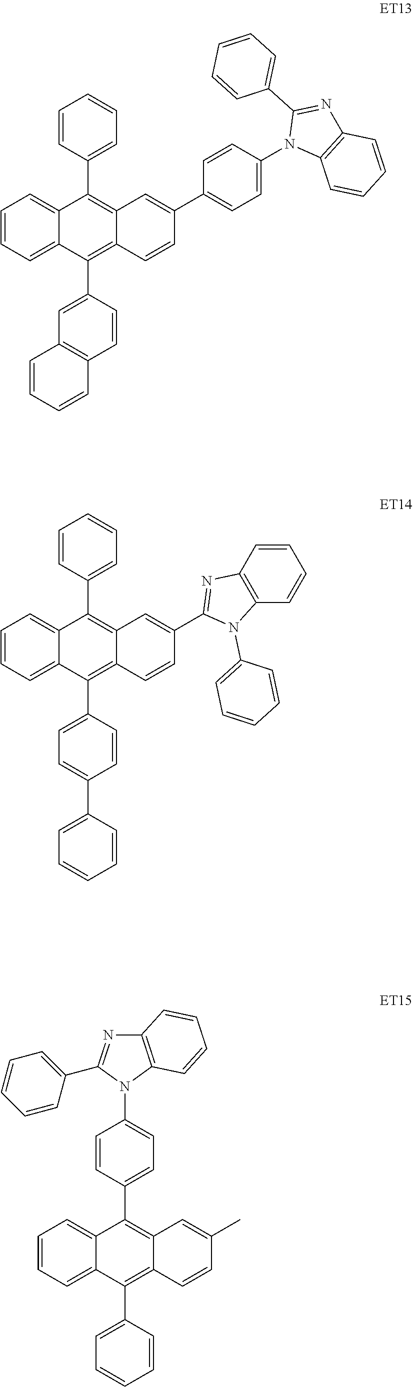 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

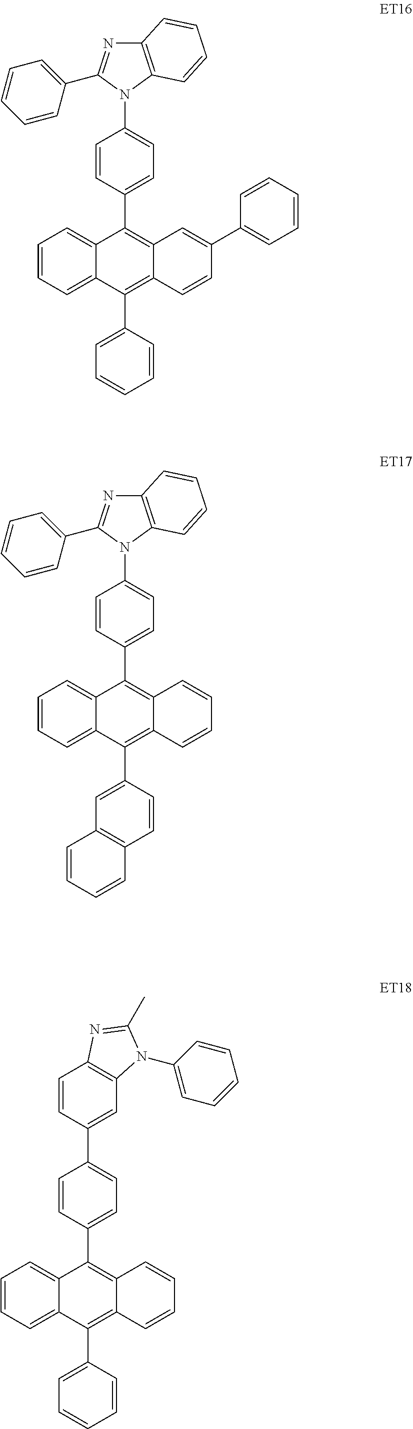 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

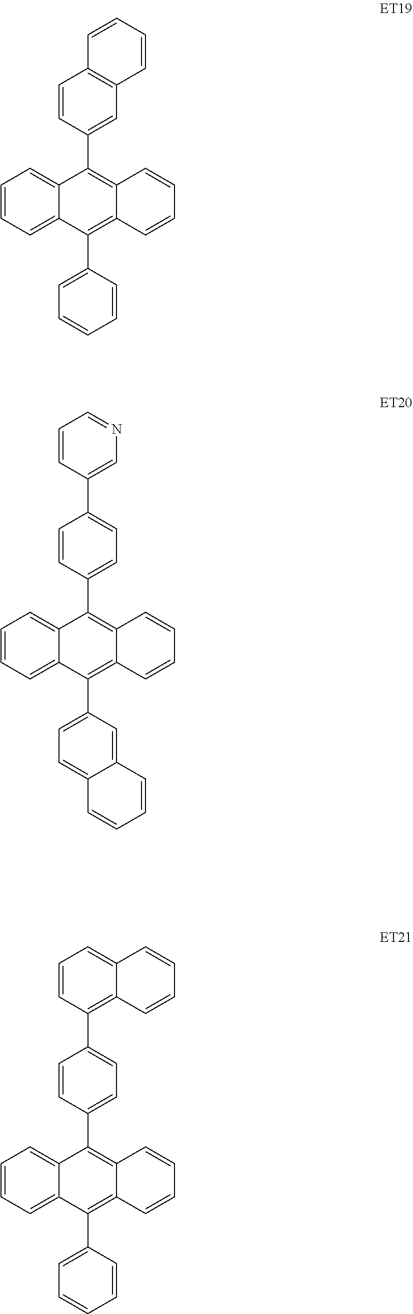

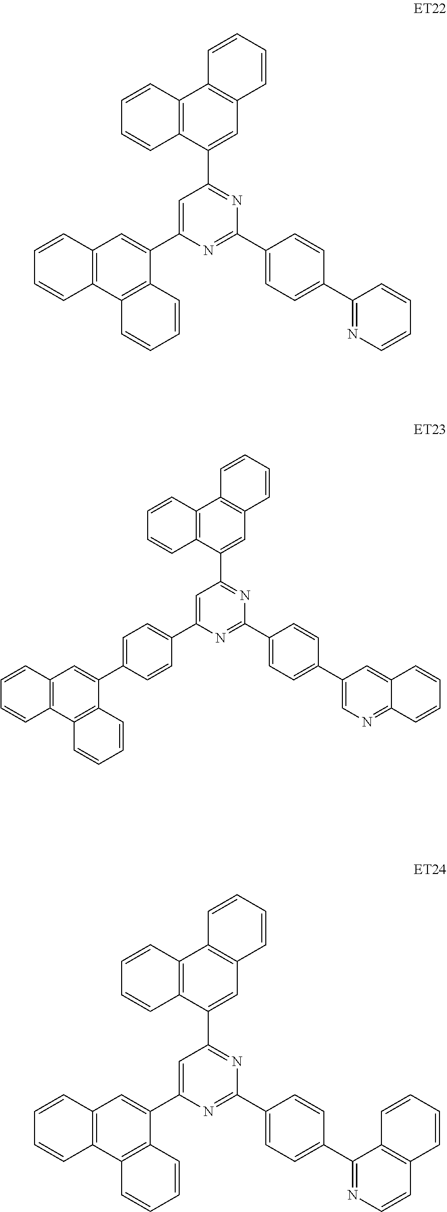 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

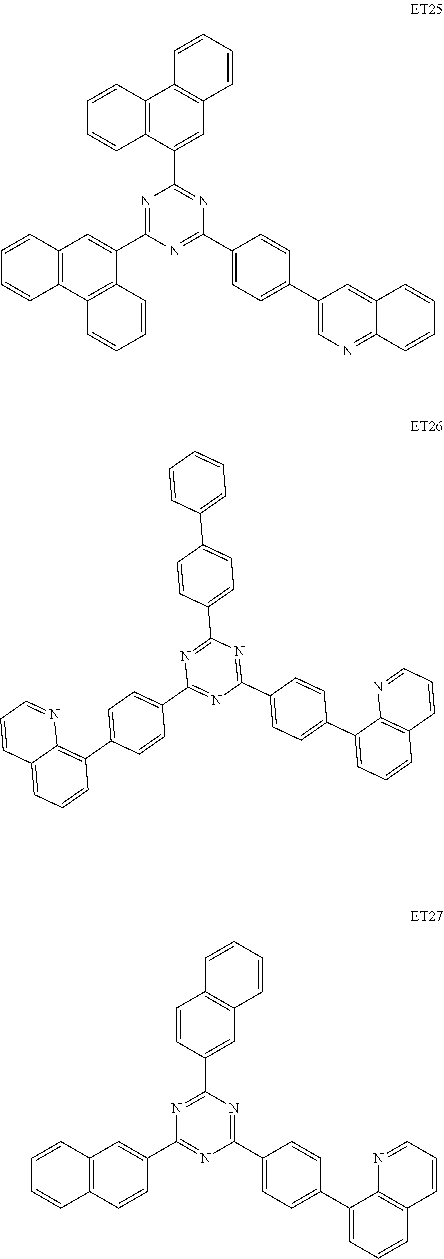 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

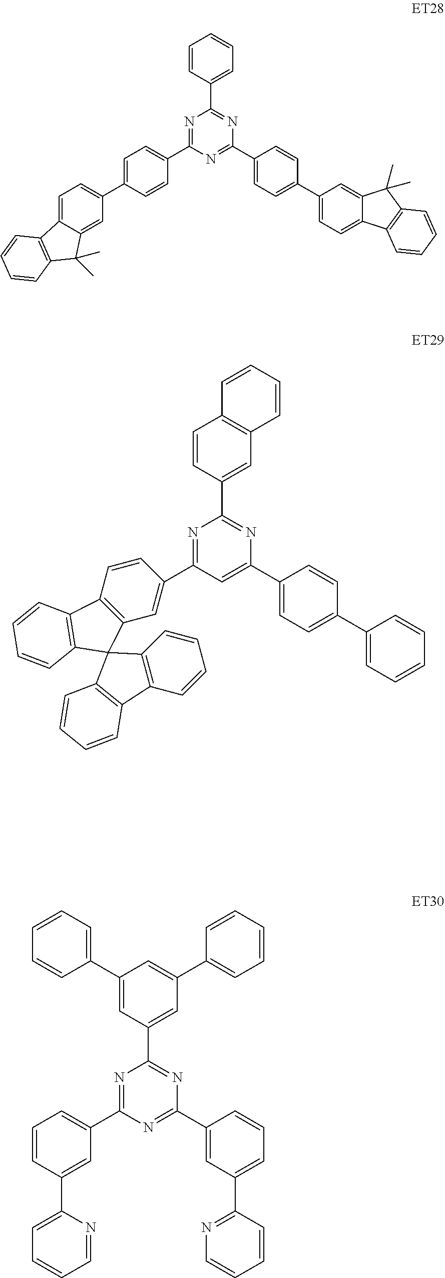 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

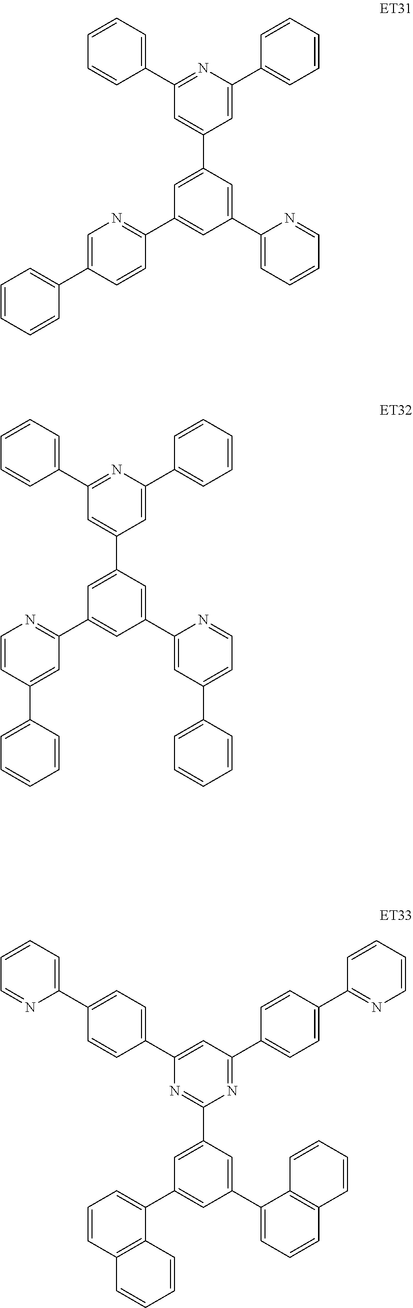 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

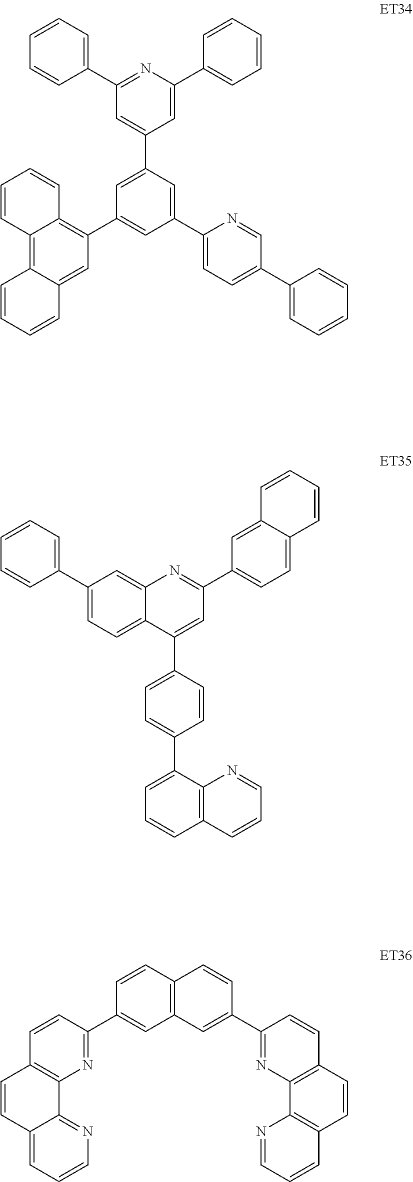 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

Thicknesses of the buffer layer, the hole blocking layer, and the electron control layer may each independently be in a range of about 20 Å to about 1,000 Å, for example, about 30 Å to about 300 Å. When the thicknesses of the buffer layer, the hole blocking layer, and the electron control layer are each within these ranges, suitable (e.g., excellent) hole blocking characteristics or suitable (e.g., excellent) electron control characteristics may be obtained without a substantial increase in driving voltage.

The electron transport region (for example, the electron transport layer in the electron transport region) may further include, in addition to the materials described above, a metal-containing material.

The metal-containing material may include at least one selected from an alkali metal complex and an alkaline earth-metal complex. A metal ion of the alkali metal complex may be selected from a Li ion, a Na ion, a K ion, a Rb ion, and a Cs ion, and a metal ion of the alkaline earth metal complex may be selected from a Be ion, a Mg ion, a Ca ion, a Sr ion, and a Ba ion. A ligand coordinated with the metal ion of the alkali metal complex or the alkaline earth metal complex may be selected from a hydroxy quinoline, a hydroxy isoquinoline, a hydroxy benzoquinoline, a hydroxy acridine, a hydroxy phenanthridine, a hydroxy phenyloxazole, a hydroxy phenylthiazole, a hydroxy diphenyloxadiazole, a hydroxy diphenylthiadiazole, a hydroxy phenylpyridine, a hydroxy phenylbenzimidazole, a hydroxy phenylbenzothiazole, a bipyridine, a phenanthroline, and a cyclopentadiene, but embodiments of the present disclosure are not limited thereto.

For example, the metal-containing material may include a Li complex. The Li complex may include, for example, Compound ET-D1 (lithium quinolate, LiQ) or ET-D2:

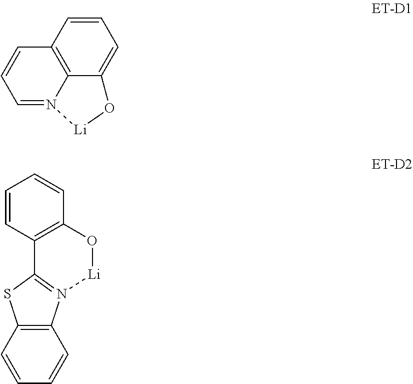

The electron transport region may include an electron injection layer that facilitates electron injection from the second electrode 190. The electron injection layer may directly contact the second electrode 190.

The electron injection layer may have i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure having a plurality of layers including (e.g., consisting of) a plurality of different materials.

The electron injection layer may include an alkali metal, an alkaline earth metal, a rare earth metal, an alkali metal compound, an alkaline earth metal compound, a rare earth metal compound, an alkali metal complex, an alkaline earth metal complex, a rare earth metal complex, or any combination thereof.

The alkali metal may be selected from Li, Na, K, Rb, and Cs. In one embodiment, the alkali metal may be Li, Na, or Cs. In one or more embodiments, the alkali metal may be Li or Cs, but embodiments of the present disclosure are not limited thereto.

The alkaline earth metal may be selected from Mg, Ca, Sr, and Ba.

The rare earth metal may be selected from Sc, Y, Ce, Tb, Yb, and Gd.

The alkali metal compound, the alkaline earth metal compound, and the rare earth metal compound may be selected from oxides and halides (for example, fluorides, chlorides, bromides, and/or iodides) of the alkali metal, the alkaline earth-metal, and the rare earth metal.

The alkali metal compound may be selected from alkali metal oxides, such as Li₂O, Cs₂O, and/or K₂O, and alkali metal halides, such as LiF, NaF, CsF, KF, LiI, NaI, CsI, KI, and/or RbI. In one embodiment, the alkali metal compound may be selected from LiF, Li₂O, NaF, LiI, NaI, CsI, and KI, but embodiments of the present disclosure are not limited thereto.

The alkaline earth metal compound may be selected from alkaline earth metal oxides, such as BaO, SrO, CaO, BaₓSr₁₋ₓO (0<x<1), and/or BaₓCa₁₋ₓO (0<x<1).

In one embodiment, the alkaline earth metal compound may be selected from BaO, SrO, and CaO, but embodiments of the present disclosure are not limited thereto.

The rare earth metal compound may be selected from YbF₃, ScF₃, Sc₂O₃, Y₂O₃, Ce₂O₃, GdF₃, and TbF₃. In one embodiment, the rare earth metal compound may be selected from YbF₃, ScF₃, TbF₃, Ybi₃, Sci₃, and Tbi₃, but embodiments of the present disclosure are not limited thereto.

The alkali metal complex, the alkaline earth metal complex, and the rare earth metal complex may include an ion of the alkali metal, the alkaline earth metal, and the rare earth metal as described above, and a ligand coordinated with a metal ion of the alkali metal complex, the alkaline earth metal complex, and the rare earth metal complex may be selected from hydroxy quinoline, hydroxy isoquinoline, hydroxy benzoquinoline, hydroxy acridine, hydroxy phenanthridine, hydroxy phenyloxazole, hydroxy phenylthiazole, hydroxy diphenyloxadiazole, hydroxy diphenylthiadiazole, hydroxy phenylpyridine, hydroxy phenylbenzimidazole, hydroxy phenylbenzothiazole, bipyridine, phenanthroline, and cyclopentadiene, but embodiments of the present disclosure are not limited thereto.

The electron injection layer may include (e.g., consist of) an alkali metal, an alkaline earth metal, a rare earth metal, an alkali metal compound, an alkaline earth metal compound, a rare earth metal compound, an alkali metal complex, an alkaline earth metal complex, a rare earth metal complex, or any combination thereof, as described above. In one or more embodiments, the electron injection layer may further include an organic material. When the electron injection layer further includes the organic material, the alkali metal, the alkaline earth metal, the rare earth metal, the alkali metal compound, the alkaline earth metal compound, the rare earth metal compound, the alkali metal complex, the alkaline earth metal complex, the rare earth metal complex, or any combination thereof may be homogeneously or non-homogeneously dispersed in a matrix including the organic material.

A thickness of the electron injection layer may be in a range of about 1 Å to about 100 Å, for example, about 3 Å to about 90 Å. When the thickness of the electron injection layer is within the ranges described above, the electron injection layer may have satisfactory electron injection characteristics without a substantial increase in driving voltage.

### Second Electrode 190

The second electrode 190 may be located on the organic layer 150 having such a structure. The second electrode 190 may be a cathode which is an electron injection electrode, and in this regard, a material for forming the second electrode 190 may be selected from a metal, an alloy, an electrically conductive compound, and a combination thereof, which have a relatively low work function.

The second electrode 190 may include at least one selected from lithium (Li), silver (Ag), magnesium (Mg), aluminum (Al), aluminum-lithium (Al—Li), calcium (Ca), magnesium-indium (Mg—In), magnesium-silver (Mg—Ag), ITO, and IZO, but embodiments of the present disclosure are not limited thereto. The second electrode 190 may be a transmissive electrode, a semi-transmissive electrode, or a reflective electrode.

The second electrode 190 may have a single-layered structure or a multi-layered structure including two or more layers.

FIG. 1 illustrates the light-emitting device 10 as including both the hole transport region 130 and the electron transport region 160, but the electron transport region 160 may be omitted (e.g., may not be included).

In one embodiment, the light-emitting device 10 may further include a capping layer positioned in a direction in which light is emitted. The capping layer may increase external luminescence efficiency according to the principle of constructive interference.

The capping layer may be an organic capping layer including (e.g., consisting of) an organic material, an inorganic capping layer including (e.g., consisting of) an inorganic material, or a composite capping layer including an organic material and an inorganic material.

The capping layer may include at least one material selected from a carbocyclic compound, a heterocyclic compound, an amine-based compound, a porphyrine derivative, a phthalocyanine derivative, a naphthalocyanine derivative, an alkali metal complex, and an alkaline earth metal complex. The carbocyclic compound, the heterocyclic compound, and the amine-based compound may be optionally substituted with a substituent containing at least one element selected from O, N, S, Se, Si, F, C₁, Br, and I. In one embodiment, the capping layer may include an amine-based compound.

In one or more embodiments, the capping layer may include a compound represented by Formula 201 and/or a compound represented by Formula 202.

In one or more embodiments, the capping layer may include a compound selected from Compounds HT28 to HT33 and Compounds CP1 to CP5 below, but embodiments of the present disclosure are not limited thereto.

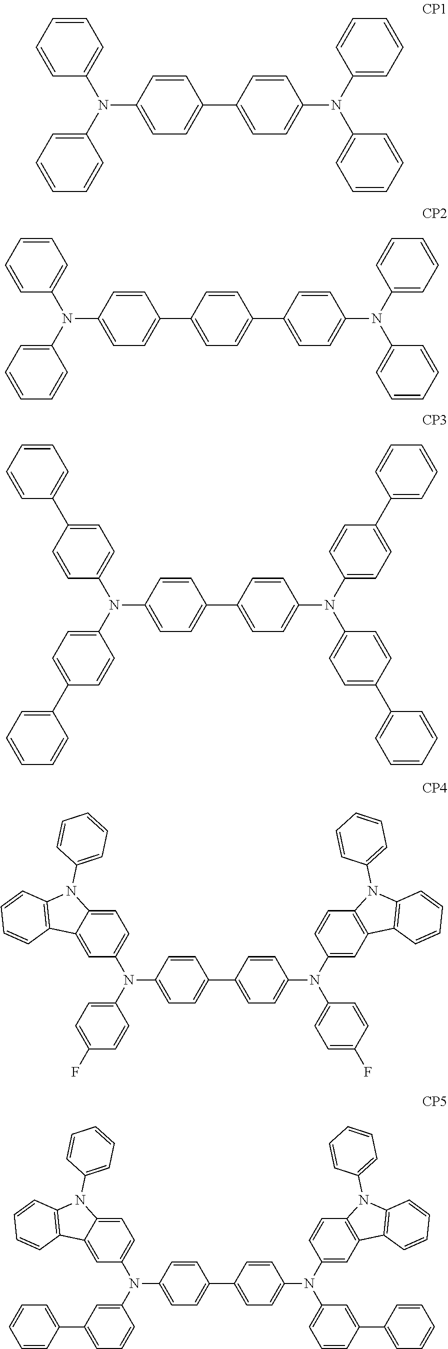 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

Hereinbefore, the light-emitting device has been described with reference to FIG. 1, but embodiments of the present disclosure are not limited thereto.

Layers constituting the hole transport region, the emission layer, and layers constituting the electron transport region may be formed in a certain region by utilizing one or more suitable methods selected from vacuum deposition, spin coating, casting, Langmuir-Blodgett (LB) deposition, ink-jet printing, laser-printing, and laser-induced thermal imaging.

When layers constituting the hole transport region, the emission layer, and layers constituting the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec by taking into account a material to be included in a layer to be formed and the structure of the layer to be formed.

When layers constituting the hole transport region, the emission layer, and layers constituting the electron transport region are formed by spin coating, the spin coating may be performed at a coating speed of about 2,000 rpm to about 5,000 rpm and at a heat treatment temperature of about 80° C. to 200° C. by taking into account a material to be included in a layer to be formed and the structure of a layer to be formed.

### Apparatus

The light-emitting device may be included in various suitable apparatuses.

Another aspect of the present disclosure provides an apparatus including the light-emitting device.

For example, the apparatus may be a light-emitting apparatus, an authentication apparatus, or an electronic apparatus, but embodiments of the present disclosure are not limited thereto.

The light-emitting apparatus may be utilized as various suitable displays, light sources, and/or the like.

The authentication apparatus may be, for example, a biometric authentication apparatus for authenticating an individual by utilizing biometric information of a biometric body (for example, a fingertip, a pupil, and/or the like).

The authentication apparatus may further include, in addition to the light-emitting device, a biometric information collector.

The electronic apparatus may be applied to personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram (ECG) displays, ultrasonic diagnostic devices, and/or endoscope displays), fish finders, various suitable measuring instruments, meters (for example, meters for a vehicle, an aircraft, and/or a vessel), projectors, and/or the like, but embodiments of the present disclosure are not limited thereto.

In one embodiment, the apparatus may further include, in addition to the light-emitting device, a thin-film transistor. Here, the thin-film transistor may include a source electrode, an activation layer, and a drain electrode, wherein the first electrode of the light-emitting device may be in electrical contact with one of the source electrode and the drain electrode of the thin-film transistor.

The thin-film transistor may further include a gate electrode, a gate insulation layer, and/or the like.

The active layer may include crystalline silicon, amorphous silicon, organic semiconductor, oxide semiconductor, and/or the like, but embodiments of the present disclosure are not limited thereto.

### Solar Cell

According to another embodiment, a solar cell includes: a first electrode; a second electrode facing the first electrode; an activation layer between the first electrode and the second electrode; a donor layer between the first electrode and the activation layer; and an electron sink layer located between the first electrode and the donor layer and includes an electron transport material, wherein the electron transport material is a transition metal, a rare earth metal, a metal oxide, an alkaline metal complex, or any combination thereof.

The solar cell may further include an interceptor layer between the activation layer and the second electrode as necessary.

### General Definition of Substituents

The term “C₁-C₆₀ alkyl group” as used herein refers to a linear or branched aliphatic saturated hydrocarbon monovalent group having 1 to 60 carbon atoms, and non-limiting examples thereof include a methyl group, an ethyl group, a propyl group, an isobutyl group, a sec-butyl group, a tert-butyl group, a pentyl group, an isoamyl group, and a hexyl group. The term “C₁-C₆₀ alkylene group” as used herein refers to a divalent group having the same structure as the C₁-C₆₀ alkyl group.

The term “C₂-C₆₀ alkenyl group” as used herein refers to a hydrocarbon group having at least one carbon-carbon double bond in the middle and/or at the terminus of the C₂-C₆₀ alkyl group, and non-limiting examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group having at least one carbon-carbon triple bond in the middle and/or at the terminus of the C₂-C₆₀ alkyl group, and non-limiting examples thereof include an ethynyl group and a propynyl group. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein Ani is the C₁-C₆₀ alkyl group), and non-limiting examples thereof include a methoxy group, an ethoxy group, and an isopropyloxy group.

The term “C₃-C₁₀ cycloalkyl group” as used herein refers to a monovalent saturated hydrocarbon monocyclic group having 3 to 10 carbon atoms, and non-limiting examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent monocyclic group having at least one heteroatom selected from N, O, Si, P, and S as a ring-forming atom, and 1 to 10 carbon atoms as the remaining ring-forming atoms, and non-limiting examples thereof include a 1,2,3,4-oxatriazolidinyl group, a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” used herein refers to a monovalent monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, Si, P, and S as a ring-forming atom, 1 to 10 carbon atoms as the remaining ring-forming atoms, and at least one carbon-carbon double bond in its ring. Non-limiting examples of the C₁-C₁₀ heterocycloalkenyl group include a 4,5-dihydro-1,2,3,4-oxatriazolylgroup, a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, a chrysenyl group, and a fluorenyl group. When the C₆-C₆₀ aryl group and the C₆-C₆₀ arylene group each include two or more rings, the two or more rings may be fused to each other.

The term “C₁-C₆₀ heteroaryl group” as used herein refers to a monovalent group having a carbocyclic aromatic system that has at least one heteroatom selected from N, O, Si, P, and S as a ring-forming atom, in addition to 1 to 60 carbon atoms. The term “C₁-C₆₀ heteroarylene group” as used herein refers to a divalent group having a carbocyclic aromatic system that has at least one heteroatom selected from N, O, Si, P, and S as a ring-forming atom, in addition to 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, an isoquinolinyl group, a carbazolyl group, a dibenzofuranyl group, and a dibenzothiofuranyl group. When the C₁-C₆₀ heteroaryl group and the C₁-C₆₀ heteroarylene group each include two or more rings, the two or more rings may be condensed with each other.

The term “C₆-C₆₀ aryloxy group” as used herein refers to a monovalent group represented by —OA₁₀₂ (wherein A₁₀₂ is the C₆-C₆₀ aryl group), and the term “C₆-C₆₀ arylthio group” as used herein refers to a monovalent group represented by —SA₁₀₃ (wherein A₁₀₃ is the C₆-C₆₀ aryl group).

The term “monovalent non-aromatic condensed polycyclic group” as used herein refers to a monovalent group having two or more rings condensed with each other, only carbon atoms (for example, having 8 to 60 carbon atoms) as ring-forming atoms, and non-aromaticity in its entire molecular structure (e.g., the molecular structure as a whole does not have aromaticity). A non-limiting example of the monovalent non-aromatic condensed polycyclic group may include an adamantyl group. The term “divalent non-aromatic condensed polycyclic group” as used herein refers to a divalent group having the same structure as that of the monovalent non-aromatic condensed polycyclic group.

The term “monovalent non-aromatic condensed heteropolycyclic group” as used herein refers to a monovalent group (for example, having 1 to 60 carbon atoms) having two or more rings condensed to each other, at least one heteroatom selected from N, O, Si, P, and S, other than carbon atoms, as a ring-forming atom, and non-aromaticity in its entire molecular structure (e.g., the molecular structure as a whole does not have aromaticity). A non-limiting example of the monovalent non-aromatic condensed heteropolycyclic group is an azaadamantyl group. The term “divalent non-aromatic condensed heteropolycyclic group” as used herein refers to a divalent group having the same structure as that of the monovalent non-aromatic condensed heteropolycyclic group.

The term “C₅-C₆₀ carbocyclic group” as used herein refers to a monocyclic or polycyclic group that includes only carbon as a ring-forming atom and consists of 5 to 60 carbon atoms. The C₅-C₆₀ carbocyclic group may be an aromatic carbocyclic group or a non-aromatic carbocyclic group. The C₅-C₆₀ carbocyclic group may be a ring, such as benzene, a monovalent group, such as a phenyl group, or a divalent group, such as a phenylene group. In one or more embodiments, depending on the number of substituents connected to the C₅-C₆₀ carbocyclic group, the C₅-C₆₀ carbocyclic group may be a trivalent group or a quadrivalent group.

The term “C₁-C₆₀ heterocyclic group” as used herein refers to a group having the same structure as the C₅-C₆₀ carbocyclic group, except that as a ring-forming atom, at least one heteroatom selected from N, O, Si, P, and S is used in addition to carbon atoms (the number of carbon atoms may be in a range of 1 to 60).

In the present specification, at least one substituent of the substituted C₅-C₆₀ carbocyclic group, the substituted C₁-C₆₀ heterocyclic group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be selected from:

deuterium, —F, —Cl, —Br, —I, a hydroxyl group, a cyano group, a nitro group, an amidino group, a hydrazino group, a hydrazone group, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —C₁, —Br, —I, a hydroxyl group, a cyano group, a nitro group, an amidino group, a hydrazino group, a hydrazone group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(C₂₁₁)(C₂₁₂)(Q₁₃), —N(Q₁₁)(Q₁₂), —B(Q₁₁)(Q₁₂), —C(═O)(Q₁₁), —S(═O)₂(Q₁₁), and —P(═O)(Q₁₁)(Q₁₂);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from deuterium, —F, —Cl, —Br, —I, a hydroxyl group, a cyano group, a nitro group, an amidino group, a hydrazino group, a hydrazone group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), and —P(═O)(Q₂₁)(Q₂₂); and

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), and —P(═O)(Q₃₁)(Q₃₂),

wherein Q₁₁ to Q₁₃, Q₂₁ to Q₂₃, and Q₃₁ to Q₃₃ may each independently be selected from hydrogen, deuterium, —F, —Cl, —Br, —I, a hydroxyl group, a cyano group, a nitro group, an amidino group, a hydrazino group, a hydrazone group, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, a monovalent non-aromatic condensed heteropolycyclic group, a biphenyl group, and a terphenyl group.

The term “Ph” as used herein refers to a phenyl group, the term “Me” as used herein refers to a methyl group, the term “Et” as used herein refers to an ethyl group, the term “ter-Bu” or “But” as used herein refers to a tert-butyl group, and the term “OMe” as used herein refers to a methoxy group.

The term “biphenyl group” as used herein refers to “a phenyl group substituted with a phenyl group”. In other words, the “biphenyl group” is a substituted phenyl group having a C₆-C₆₀ aryl group as a substituent.

The term “terphenyl group” as used herein refers to “a phenyl group substituted with a biphenyl group”. In other words, the “terphenyl group” is a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula.

Hereinafter, a light-emitting device according to embodiments will be described in more detail with reference to Examples.

### EXAMPLES

### Preparation Example 1: Preparation of Quantum Dot Composition

Quantum dots (particle diameter: 8 nm) having a structure of core/shell=InP (core)/ZnSe/ZnS (shell) were mixed in octane as a solvent at a concentration of 5 mg/ml to prepare a quantum dot composition.

### Example 1

As an anode, an ITO-deposited substrate was cut to a size of 50 mm×50 mm×0.7 mm, sonicated by utilizing isopropyl alcohol and pure water each for 5 minutes, and then cleaned by irradiation of ultraviolet rays and exposure to ozone at the same time for 30 minutes. Then, the ITO substrate was loaded onto a vacuum deposition apparatus.

PEDOT:PSS were spin-coated on the ITO substrate and dried to form a hole injection layer having a thickness of 40 nm, and TFB was spin-coated on the hole injection layer and dried to form a hole transport layer having a thickness of 40 nm.

Liq was vacuum-deposited on the hole transport layer to form an electron sink layer having a thickness of 4 nm.

The quantum dot composition of Preparation Example 1 was spin-coated on the electron sink layer for 30 seconds at a coating speed of 3,500 rpm, naturally dried (e.g., air dried) for 5 minutes at a room temperature (e.g., about 25° C.), and then dried for 30 minutes at a temperature of 150° C., thereby completing the formation of an emission layer having a thickness of 20 nm.

ZnMgO nanoparticles were spin-coated on the emission layer and then naturally dried to form an electron transport layer having a thickness of 40 nm, and Al was deposited on the electron injection layer to form a cathode having a thickness of 150 nm, thereby completing the manufacture of a light-emitting device.

### Comparative Example 1

A light-emitting device was manufactured substantially in the same manner as in Example 1, except that an electron sink layer was not formed.

### Evaluation Example 1

With respect to each of the light-emitting devices manufactured according to Example 1 and Comparative Example 1, driving voltage, current density, efficiency, and CIE coordinates were measured by utilizing a current-voltage meter (Keithley SMU 236) and a luminance meter (PR650), and results thereof are shown in Table 1.

TABLE 1

| | | | | | | | | Maximum |
|---|---|---|---|---|---|---|---|---|
| | | | | | | | | external |
| | Electron | Driving | Current | Current | Power | | | quantum |
| | sink | voltage | density | efficiency | efficiency | | | efficiency |
| | layer | (V) | (mA/cm²) | (cd/A) | (lm/W) | CIE_x | CIE_y | (Q.E) (%) |
| Example 1 | Liq | 3.8 | 16.1 | 3.6 | 3.0 | 0.7 | 0.3 | 4.0 |
| Comparative | — | 4.4 | 20.5 | 2.8 | 2.0 | 0.7 | 0.3 | 3.1 |
| Example 1 | | | | | | | | |

Referring to Table 1, it is confirmed that the light-emitting device manufactured according to Example 1 has low driving voltage, improved current efficiency, improved power efficiency, and improved maximum external quantum efficiency, compared to the light-emitting device manufactured according to Comparative Example 1. Although not limited to any specific theory, because the light-emitting device manufactured according to Example 1 includes the electron sink layer, electrons in the emission layer may be prevented or substantially prevented from leaking to the hole transport layer, resulting in improvement in luminescence efficiency.

### Evaluation Example 2: Evaluation of Roll-Off Characteristics

With respect to each of the light-emitting devices manufactured according to Example 1 and Comparative Example 1, current efficiency according to luminance was measured by utilizing Keithley SMU 236 and a luminance meter PR650, and results thereof are shown in FIG. 2.

As shown in FIG. 2, it is confirmed that the light-emitting device manufactured according to Example 1 has improved current efficiency at the same luminance and improved roll-off characteristics, compared to the light-emitting device manufactured according to Comparative Example 1. Although not limited to any specific theory, because the light-emitting device manufactured according to Example 1 includes an electron sink layer, electrons in an emission layer may be prevented or substantially prevented from leaking to a hole transport layer, resulting in improvement in current efficiency and roll-off characteristics.

The light-emitting device may prevent or substantially prevent electrons from leaking from a quantum dot emission layer to a hole transport region and may improve hole injection to the emission layer. Thus, a high-quality light-emitting device having high efficiency and long lifespan may be provided.

The use of “may” when describing embodiments of the present invention refers to “one or more embodiments of the present invention.” Also, the term “exemplary” is intended to refer to an example or illustration. It will be understood that when an element or layer is referred to as being “on”, “connected to”, “coupled to”, or “adjacent to” another element or layer, it can be directly on, connected to, coupled to, or adjacent to the other element or layer, or one or more intervening elements or layers may be present. In contrast, when an element or layer is referred to as being “directly on,” “directly connected to”, “directly coupled to”, or “immediately adjacent to” another element or layer, there are no intervening elements or layers present.

As used herein, the term “substantially,” “about,” and similar terms are used as terms of approximation and not as terms of degree, and are intended to account for the inherent deviations in measured or calculated values that would be recognized by those of ordinary skill in the art. Moreover, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a), and 35 U.S.C. § 132(a).

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims, and equivalents thereof.

What is claimed is:

1. A light-emitting device comprising:
a first electrode;
a second electrode facing the first electrode;
an emission layer between the first electrode and the second electrode and comprising quantum dots;
a hole transport region between the first electrode and the emission layer; and
an electron sink layer between the emission layer and the hole transport region and comprising an electron transport material,
wherein the electron transport material comprises a metal, a metal oxide, a metal-containing material, or any combination thereof.

2. The light-emitting device of claim 1, wherein the electron transport material comprises an alkali metal, an alkaline earth metal, a rare earth metal, a transition metal, one or more metal oxides thereof, an alkaline metal complex, an alkaline earth metal complex, or any combination thereof.

3. The light-emitting device of claim 1, wherein the electron transport material comprises Yb, Ag, ZnO, TiO₂, WO₃, SnO₂, ITO, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Liq, or any combination thereof.

4. The light-emitting device of claim 1, wherein the electron transport material comprises Yb, Ag, ITO, ZnO, ZnMgO, Liq, or any combination thereof.

5. The light-emitting device of claim 1, wherein the electron sink layer consists of the electron transport material.

6. The light-emitting device of claim 1, wherein the hole transport region comprises a hole transport material, and
the hole transport material and the electron transport material are different from each other.

7. The light-emitting device of claim 1, wherein the electron sink layer is at an interface between the hole transport region and the emission layer.

8. The light-emitting device of claim 1, wherein the hole transport region comprises a hole injection layer, a hole transport layer, a buffer layer, or any combination thereof, and
the electron sink layer is at an interface between the emission layer and a layer adjacent to the second electrode from among layers included in the hole transport region.

9. The light-emitting device of claim 1, wherein the hole transport region comprises a hole transport layer, and
the electron sink layer is at an interface between the hole transport layer and the emission layer.

10. The light-emitting device of claim 1, wherein a thickness of the electron sink layer is from 0.01 nm to 20 nm.

11. The light-emitting device of claim 1, wherein the quantum dots in the emission layer comprise a Group II-VI semiconductor compound, a Group III-VI semiconductor compound, a Group III-V semiconductor compound, a Group IV-VI semiconductor compound, a Group IV element or compound, a Group semiconductor compound, or any combination thereof.

12. The light-emitting device of claim 1, wherein the quantum dots in the emission layer comprise a Group III-V semiconductor compound.

13. The light-emitting device of claim 1, wherein the quantum dots in the emission layer comprise InN, InP, InAs, InSb, InAsP, InGaAs, InGaP, GaP, GaN, GaSb, GaAs, ZnS, ZnSe, ZnTe, ZnO, HgS, HgSe, HgTe, ZnSeS, ZnSeTe, ZnSTe, CdS, CdSe, CdTe, CdSeS, CdSeTe, CdSTe, HgSeS, HgSeTe, HgSTe, CdZnS, CdZnSe, CdZnTe, CdHgS, CdHgSe, CdHgTe, HgZnS, HgZnSe, HgZnTe, ZnCdSe, AgInS, AgInS₂, CuInS, CuInS₂, CuGaO₂, AgGaO₂, AgAlO₂, CulnZnS, In₂S₃, Ga₂S₃, InGaS₃, InGaSe₃, or any combination thereof.

14. The light-emitting device of claim 1, wherein the quantum dots in the emission layer comprise InP and do not comprise cadmium (Cd).

15. The light-emitting device of claim 1, wherein the quantum dots in the emission layer each have a core-shell structure comprising a core comprising a first semiconductor crystal and a shell comprising a second semiconductor crystal.

16. The light-emitting device of claim 15, wherein the first semiconductor crystal comprises InN, InP, InAs, InSb, InAsP, InGaAs, InGaP, GaP, GaN, GaSb, GaAs, ZnS, ZnSe, ZnTe, HgS, HgSe, HgTe, ZnSeS, ZnSeTe, CdS, CdSe, CdTe, CdSeTe, CdZnSe, ZnCdSe, AgInS₂, CuInS, CulnZnS, or any combination thereof, and the second semiconductor crystal comprises ZnS, ZnSe, ZnTe, ZnSeS, ZnSeTe, In₂S₃, Ga₂S₃, or any combination thereof.

17. The light-emitting device of claim 1, further comprising an electron transport region between the emission layer and the second electrode,
wherein the first electrode is an anode, and
the second electrode is a cathode.

18. The light-emitting device of claim 17, wherein the electron transport region comprises ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC₆₀BM, PC₇₀BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof.

19. The light-emitting device of claim 17, wherein the electron transport region comprises an electron transport layer, and
the electron transport layer has a thickness of 20 nm to 150 nm.

20. An apparatus comprising:
a thin-film transistor comprising a source electrode, a drain electrode, and an activation layer; and
the light-emitting device of claim 1,
wherein the first electrode of the light-emitting device is electrically connected with the source electrode or the drain electrode of the thin-film transistor.
